(19) United States
(12) Patent Application Publication
(10) Pub. No.: US 2024/0030105 A1
(43) Pub. Date: Jan. 25, 2024

(54) SEMICONDUCTOR DEVICE

(71) Applicant: ROHM CO., LTD., Kyoto-shi (JP)

(72) Inventors: Yoshizo OSUMI, Kyoto-shi (JP); Yasushi HAMAZAWA, Kyoto-shi (JP); Tomohira KIKUCHI, Kyoto-shi (JP)

(21) Appl. No.: 18/480,233

(22) Filed: Oct. 3, 2023

Related U.S. Application Data
(63) Continuation of application No. PCT/JP2022/012573, filed on Mar. 18, 2022.

(30) Foreign Application Priority Data
Apr. 16, 2021 (JP) 2021-069749

(51) Int. Cl. H01L 23/495; H01L 23/31; H01L 23/00

(52) U.S. Cl. CPC H01L 23/49503; H01L 23/49575; H01L 23/3135; H01L 24/48; H01L 23/49541; H01L 2224/48175

(57) ABSTRACT

A semiconductor device includes: a first die pad; a second die pad; a first semiconductor element on the first die pad; a second semiconductor element on the second die pad; an insulating element electrically connected to the first semiconductor element and the second semiconductor element and electrically insulating the first and second semiconductor elements from each other; a sealing resin covering the first semiconductor element, the second semiconductor element and the insulating element; and a support member on which the insulating element is mounted, where the support member includes an insulating portion containing a resin. The first die pad and the second die pad are spaced apart from each other in a first direction orthogonal to a thickness direction of the first semiconductor element. The support member is supported by at least one of the first die pad, the second die pad and the sealing resin.

### TECHNICAL FIELD

The present disclosure relates to a semiconductor device including a plurality of semiconductor elements and an insulating element that insulates the semiconductor elements from each other.

### BACKGROUND ART

Inverter devices have been used in electric vehicles (including hybrid vehicles) and consumer electronics. For example, an inverter device includes a semiconductor device and a power semiconductor, such as an insulated gate bipolar transistor (IGBT) or a metal-oxide-semiconductor field-effect transistor (MOSFET). The semiconductor device includes a control element (controller) and a drive element (gate driver). For the inverter device, a control signal is outputted from an external source. The control element receives and converts the control signal into a pulse width modulation (PWM) control signal, which is then transmitted to the drive element. According to the PWM control signal, the drive element drives, for example, six switching elements to be ON and OFF with desired timing. In this way, the inverter device converts a direct current power into a three-phase alternating current power for driving a motor. JP-A-2016-207714 discloses a semiconductor device for use in a motor drive device.

The semiconductor device disclosed in JP-A-2016-207714 uses power supplies of different voltages for the control element and for the drive element. Hence, the conductive path to the control element and the conductive path to the drive element are supplied with different power supply voltages. For this reason, an insulating element is interposed between the two conductive paths to improve the dielectric strength of the semiconductor device. The insulating element is mounted on the same die pad with either the control element or the drive element. A significant difference in the power supply voltage between the two conductive paths can increase the possibility of dielectric breakdown of the insulating element. It is therefore desirable to take some measures.

### BRIEF DESCRIPTION OF THE DRAWINGS

FIG. 1 is a plan view of a semiconductor device according to a first embodiment of the present disclosure.

FIG. 2 is a plan view corresponding to FIG. 1, with a sealing resin shown as transparent.

FIG. 3 is a front view of the semiconductor device shown in FIG. 1.

FIG. 4 is a rear view of the semiconductor device shown in FIG. 1.

FIG. 5 is a left-side view of the semiconductor device shown in FIG. 1.

FIG. 6 is a sectional view taken along line VI-VI of FIG. 2.

FIG. 7 is a sectional view taken along line VII-VII of FIG. 2.

FIG. 8 is a partially enlarged view of FIG. 6.

FIG. 9 is a schematic view of an insulating element and a support member shown in FIG. 6.

FIG. 10 is a plan view of the semiconductor device shown in FIG. 1, for illustrating a process of forming the support member.

FIG. 11 is a plan view of the semiconductor device shown in FIG. 1, for illustrating a process of forming the support member.

FIG. 12 is a partially enlarged sectional view of the semiconductor device shown in FIG. 1, for illustrating a process of forming the support member.

FIG. 13 is a partially enlarged sectional view of the semiconductor device shown in FIG. 1, for illustrating a process of forming the support member.

FIG. 14 is a partially enlarged sectional view of the semiconductor device shown in FIG. 1, for illustrating a process of forming the support member.

FIG. 15 is a plan view of the semiconductor device shown in FIG. 1, for illustrating a process of forming the support member.

FIG. 16 is a partially enlarged sectional view of a semiconductor device according to a variation of the first embodiment of the present disclosure.

FIG. 17 is a plan view of a semiconductor device according to a second embodiment of the present disclosure, with a sealing resin shown as transparent.

FIG. 18 is a sectional view taken along line XVIII-XVIII of FIG. 17.

FIG. 19 is a partially enlarged view of FIG. 18.

FIG. 20 is a plan view of a semiconductor device according to a third embodiment of the present disclosure, with a sealing resin shown as transparent.

FIG. 21 is a sectional view taken along line XXI-XXI of FIG. 20.

FIG. 22 is a partially enlarged view of FIG. 21.

FIG. 23 is a plan view of a semiconductor device according to a fourth embodiment of the present disclosure, with a sealing resin shown as transparent.

FIG. 24 is a sectional view taken along line XXIV-XXIV of FIG. 23.

FIG. 25 is a plan view of the semiconductor device shown in FIG. 23, for illustrating a process of forming a support member.

FIG. 26 is a plan view of the semiconductor device shown in FIG. 23, for illustrating a process of forming the support member.

FIG. 27 is a plan view of a semiconductor device according to a fifth embodiment of the present disclosure, with a sealing resin shown as transparent.

FIG. 28 is a front view of the semiconductor device shown in FIG. 27.

FIG. 29 is a rear view of the semiconductor device shown in FIG. 27.

FIG. 30 is a sectional view taken along line XXX-XXX of FIG. 27.

FIG. 31 is a sectional view taken along line XXXI-XXXI of FIG. 27.

FIG. 32 is a plan view of the semiconductor device shown in FIG. 27, for illustrating a process of forming a support member.

FIG. 33 is a plan view of the semiconductor device shown in FIG. 27, for illustrating a process of forming the support member.

FIG. 34 is a plan view of a semiconductor device according to a sixth embodiment of the present disclosure, with a sealing resin shown as transparent.

FIG. 35 is a sectional view taken along line XXXV-XXXV of FIG. 34.

FIG. 36 is a sectional view taken along line XXXVI-XXXVI of FIG. 34.

FIG. 37 is a plan view of the semiconductor device shown in FIG. 34, for illustrating a process of forming a support member.

FIG. 38 is a plan view of the semiconductor device shown in FIG. 34, for illustrating a process of forming the support member.

FIG. 39 is a plan view of a semiconductor device according to a seventh embodiment of the present disclosure, with a sealing resin shown as transparent.

FIG. 40 is a partially enlarged view of FIG. 39.

FIG. 41 is a sectional view taken along line XLI-XLI of FIG. 39.

FIG. 42 is a schematic view of an insulating element and a support member shown in FIG. 41.

### DETAILED DESCRIPTION OF EMBODIMENTS

The following describes embodiments of the present disclosure with reference to the accompanying drawings.

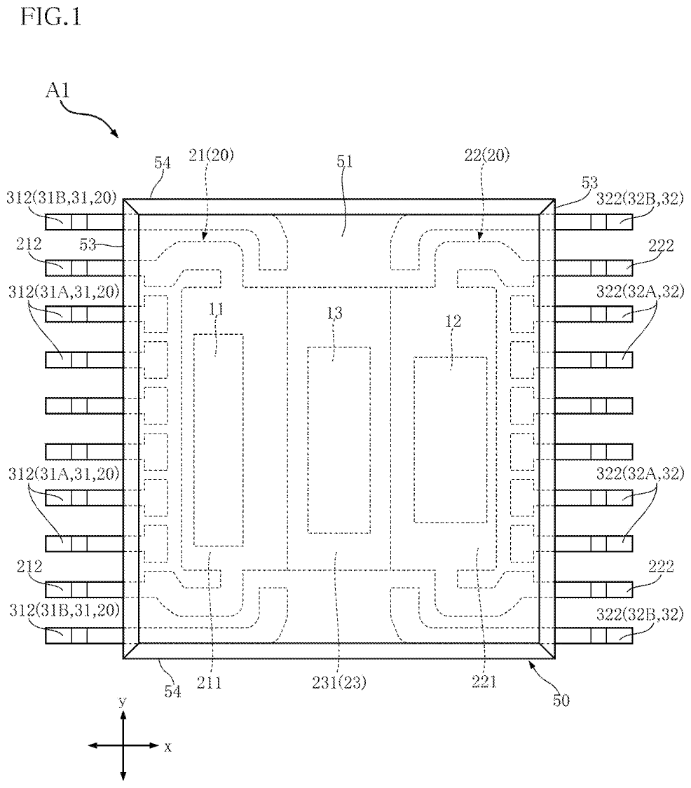

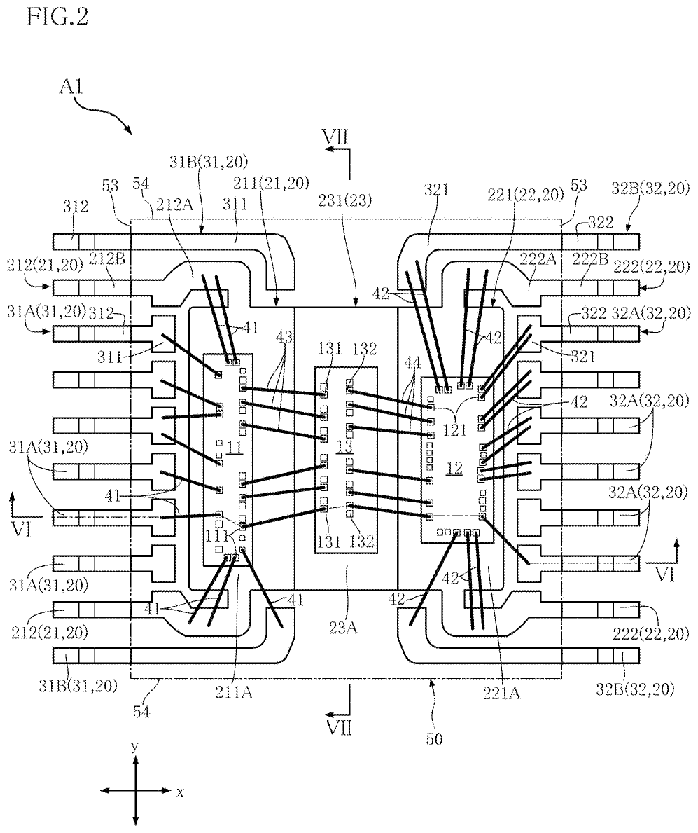

With reference to FIGS. 1 to 9, the following describes a semiconductor device A1 according to a first embodiment of the present disclosure. The semiconductor device A1 includes a first semiconductor element 11, a second semiconductor element 12, an insulating element 13, a plurality of conductive members 20, a support member 23, a bonding layer 29, a plurality of first wires 41, a plurality of second wires 42, a plurality of third wires 43, a plurality of fourth wires 44 and a sealing resin 50. The conductive members 20 include a first die pad 21, a second die pad 22, a plurality of first terminals 31 and a plurality of second terminals 32. The semiconductor device Al is designed for surface mounting on the wiring board of an inverter device for an electric vehicle (or a hybrid vehicle), for example. The semiconductor device A1 is provided in a small outline package (SOP). The packaging of the semiconductor device A1, however, is not limited to SOP. For the convenience of description, FIG. 2, shows the sealing resin 50 as transparent and indicates the sealing resin 50 with imaginary lines (two-dot-dash lines).

In the description of the semiconductor device A1, the thickness direction of the first semiconductor element 11, the second semiconductor element 12 and the insulating element 13 is referred to as a “thickness direction z”. A direction orthogonal to the thickness direction z is referred to as a “first direction x”. The direction orthogonal to both the thickness direction z and the first direction x is referred to as a “second direction y”.

The first semiconductor element 11, the second semiconductor element 12 and the insulating element 13 are integral to the functionality of the semiconductor device A1. In the semiconductor device A1, the first semiconductor element 11, the second semiconductor element 12 and the insulating element 13 are discrete components. In the first direction x, the second semiconductor element 12 is located opposite the first semiconductor element 11 with respect to the insulating element 13. As viewed in the thickness direction z, each of the first semiconductor element 11, the second semiconductor element 12 and the insulating element 13 has a rectangle shape with its longer sides extending in the second direction y.

The first semiconductor element 11 is a controller (control element) for a gate driver that drives a switching element, such as an IGBT or a MOSFET. The first semiconductor element 11 includes a circuit for converting a control signal received for example from an ECU into a PWM control signal, a transmitting circuit for transmitting the PWM control signal to the second semiconductor element 12, and a receiving circuit for receiving an electrical signal from the second semiconductor element 12. The second semiconductor element 12 is the gate driver (drive element) for driving the switching element. The second semiconductor element 12 includes a receiving circuit for receiving a PWM control signal, a circuit for driving the switching element based on the PWM control signal, and a transmitting circuit for transmitting an electrical signal to the first semiconductor element 11. Examples of electrical signals include an output signal of a temperature sensor disposed near the motor.

The insulating element 13 implements insulated transmission of a PWM control signal and other electrical signals. In the semiconductor device Al, the insulating element 13 is an inductive-type insulating element. One example of the inductive-type insulating element 13 is an insulation transformer, which transmits a signal in an insulated condition through inductive coupling between two inductors (coils). The insulating element 13 includes a substrate made of silicon. Inductors made of copper (Cu) are disposed on the substrate. The inductors include a primary inductor and a secondar inductor disposed one above the other in the thickness direction z. A dielectric layer, which may be made of silicon dioxide (SiO₂), is interposed between the primary inductor and the secondary inductor. By the dielectric layer, the primary inductor and the secondar inductor are electrically isolated. In another example, the insulating element 13 may be of a capacitive type. One example of the capacitive-type insulating element 13 is a capacitor.

In the semiconductor device A1, the voltage applied to the first semiconductor element 11 differs from the voltage applied to the second semiconductor element 12. This causes a potential difference between the first semiconductor element 11 and the second semiconductor element 12. In the semiconductor device A1, the power supply voltage for the second semiconductor element 12 is higher than that for the first semiconductor element 11.

In the semiconductor device A1, the insulating element 13 electrically insulates a first circuit that includes the first semiconductor element 11 and a second circuit that includes the second semiconductor element 12 from each other. The insulating element 13 is electrically connected to both the first circuit and the second circuit. The first circuit, which includes the first semiconductor element 11, additionally includes the first die pad 21, the first terminals 31, the first wires 41 and the third wire 43. The second circuit, which includes the second semiconductor element 12, additionally includes the second die pad 22, the second terminals 32, the second wires 42 and the fourth wires 44. The first circuit and the second circuit are held at different potentials. In the semiconductor device A1, the potential of the second circuit is higher than the potential of the first circuit. Under these conditions, the insulating element 13 transmits signals between the first circuit and the second circuit. In an inverter device for an electric vehicle or hybrid vehicle, for example, the first semiconductor element 11 has a ground at about 0 V, but the second semiconductor element 12 has a ground that can be subjected to a transient voltage of 600 v or higher.

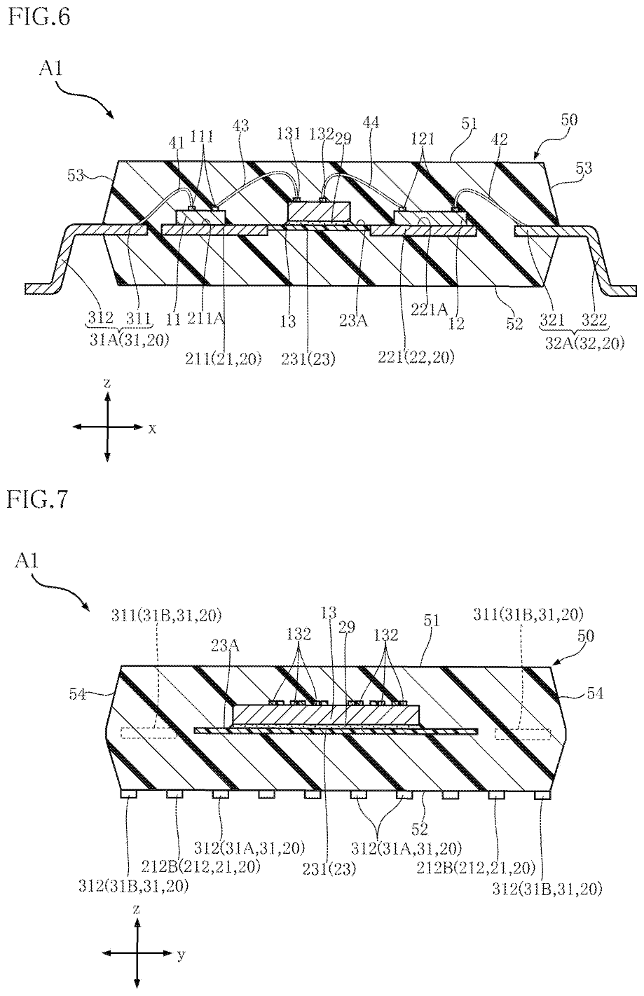

As shown in FIGS. 2 and 6, the first semiconductor element 11 includes a plurality of first electrodes 111. The first electrodes 111 are disposed on the upper surface of the first semiconductor element 11 (the surface facing in the same direction as a first mounting surface 211A of a first pad portion 211 of the first die pad 21 described later). The composition of the first electrodes 111 includes aluminum (A1), for example. That is, each first electrodes 111 contains aluminum. The first electrodes 111 are electrically connected to the circuit formed in the first semiconductor element 11.

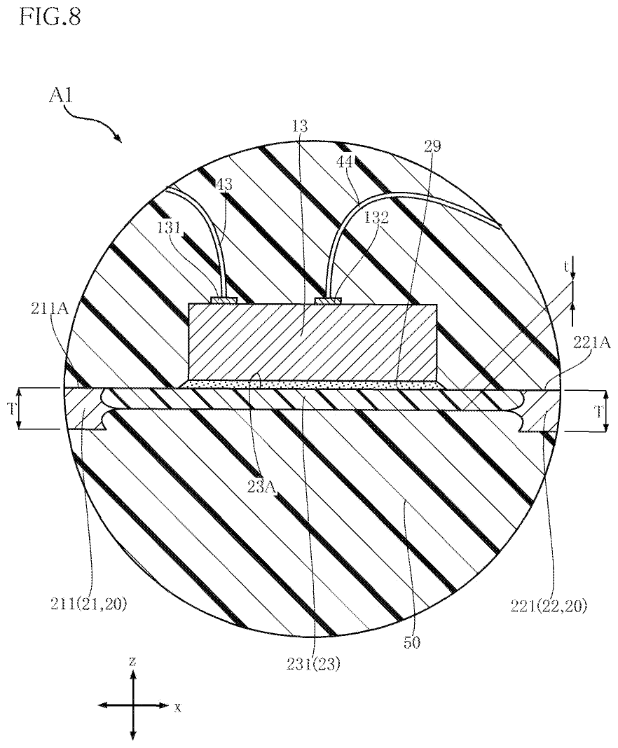

As shown in FIGS. 2 and 6, the insulating element 13 is located between the first semiconductor element 11 and the second semiconductor element 12 in the first direction x. As shown in FIGS. 2 and 8, the insulating element 13 includes a plurality of first relay electrodes 131 and a plurality of second relay electrodes 132. The first relay electrodes 131 and the second relay electrodes 132 are disposed on the upper surface of the insulating element 13 (the surface facing in the same direction as a mounting surface 23A of the support member 23 described later). The first relay electrodes 131 are aligned in the second direction y and are closer to the first semiconductor element 11 than to the second semiconductor element 12 in the first direction x. The second relay electrodes 132 are aligned in the second direction y and are closer to the second semiconductor element 12 than to the first semiconductor element 11 in the first direction x.

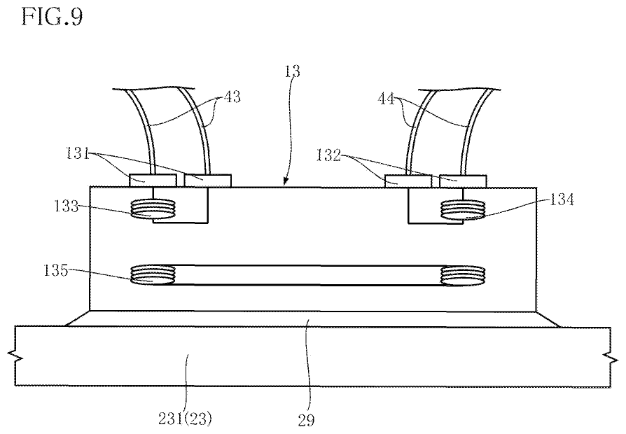

As shown in FIG. 9, the insulating element 13 also includes a first transmitting/receiving portion 133, a second transmitting/receiving portion 134 and a relay portion 135. The first transmitting/receiving portion 133, the second transmitting/receiving portion 134 and the relay portion 135 are composed of inductors. The first transmitting/receiving portion 133 and the second transmitting/receiving portion 134 are spaced apart from each other in the first direction x. The first transmitting/receiving portion 133 is electrically connected to the first relay electrodes 131 and then to the first semiconductor element 11 via the third wires 43. The second transmitting/receiving portion 134 is electrically connected to the second relay electrodes 132 and then to the second semiconductor element 12 via the fourth wires 44.

As shown in FIG. 9, the relay portion 135 is spaced apart from the first transmitting/receiving portion 133 and the second transmitting/receiving portion 134 in the thickness direction z. A dielectric layer (not shown) made of, for example, silicon dioxide is interposed between the relay portion 135 and each of the first transmitting/receiving portion 133 and the second transmitting/receiving portion 134. The relay portion 135 transmits signals between the first transmitting/receiving portion 133 and the second transmitting/receiving portion 134. In the thickness direction z, the relay portion 135 is located closer to the support member 23 than the first transmitting/receiving portion 133 and the second transmitting/receiving portion 134. The relay portion 135 is held at a potential between the potential of the first transmitting/receiving portion 133 and the potential of the second transmitting/receiving portion 134.

As shown in FIGS. 2 and 6, the second semiconductor element 12 includes a plurality of second electrodes 121. The second electrodes 121 are disposed on the upper surface of the second semiconductor element 12 (the surface facing in the same direction as a second mounting surface 221A of a second pad portion 221 of the second die pad 22 described later). The second electrodes 121 contain aluminum, for example. The second electrodes 121 are electrically connected to the circuit formed in the second semiconductor element 12.

The conductive members 20 form conductive paths connecting the first semiconductor element 11, the second semiconductor element 12 and the insulating element 13 to a wiring board when the semiconductor device A1 is mounted on the wiring board. The conductive members 20 are formed out of a lead frame 80, which will be described later. The lead frame 80 contains copper. As described above, the conductive members 20 include the first die pad 21, the second die pad 22, the first terminals 31 and the second terminals 32. As shown in FIGS. 1 and 2, the first die pad 21 and the second die pad 22 are spaced apart from each other in the first direction x. The first semiconductor element 11 is mounted on the first die pad 21, and the second semiconductor element 12 is mounted on the second die pad 22. The second die pad 22 is subjected to a higher voltage than the first die pad 21.

As shown in FIG. 2, the first die pad 21 includes a first pad portion 211 and two first suspending-lead portions 212. The first pad portion 211 is where the first semiconductor element 11 is mounted. As shown in FIGS. 6 and 7, the first pad portion 211 has a first mounting surface 211A facing in the thickness direction z. The first semiconductor element 11 is bonded to the first mounting surface 211A via a conductive bonding material (such as solder or a metal paste) not shown in the figures. The first pad portion 211 is covered with the sealing resin 50. The first pad portion 211 may have a thickness of 150 μm or greater and 200 μm or less, for example.

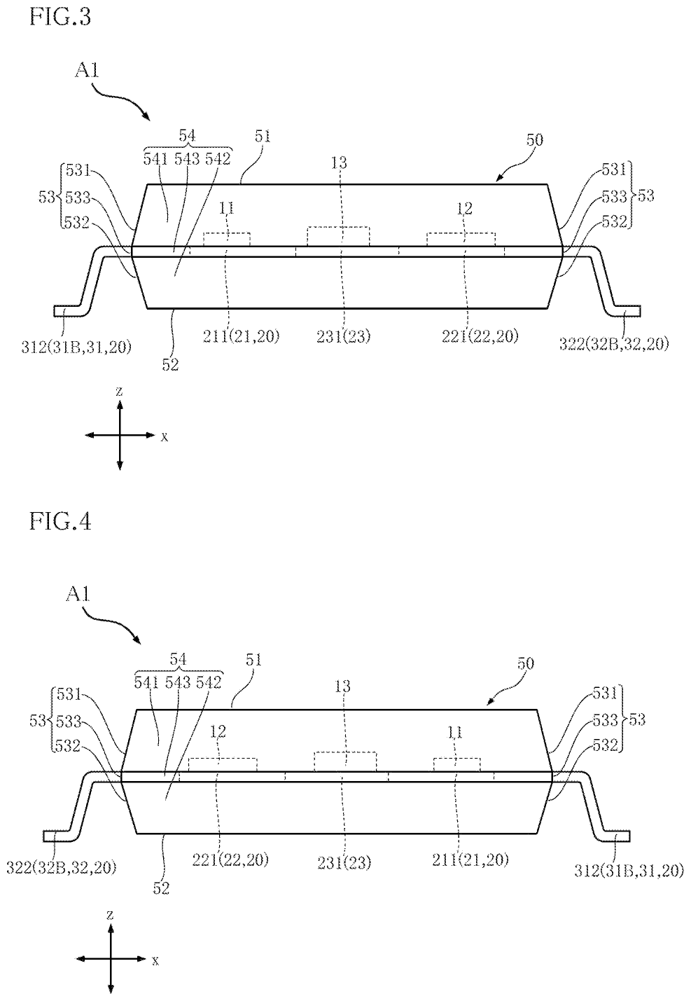

As shown in FIG. 2, the two first suspending-lead portions 212 are connected to the opposite ends of the first pad portion 211 in the second direction y. Each of the two first suspending-lead portions 212 includes a covered portion 212A and an exposed portion 212B. The covered portion 212A is connected to the first pad portion 211 and covered with the sealing resin 50. The covered portion 212A includes a section extending in the first direction x. The exposed portion 212B is connected to the covered portion 212A and exposed from the sealing resin 50. As viewed in the thickness direction z, the exposed portion 212B extends in the first direction x. As viewed in the second direction y, the exposed portion 212B is bent into a gull wing shape (see FIGS. 3 and 4). The surface of the exposed portion 212B may be plated with tin (Sn), for example.

As shown in FIG. 2, the second die pad 22 includes a second pad portion 221 and two second suspending-lead portions 222. The second pad portion 221 is where the second semiconductor element 12 is mounted. As shown in FIG. 6, the second pad portion 221 has a second mounting surface 221A facing in the thickness direction z. The second semiconductor element 12 is bonded to the second mounting surface 221A via a conductive bonding material (such as solder or a metal paste) not shown in the figures. The second pad portion 221 is covered with the sealing resin 50. The second pad portion 221 may have a thickness of 150 μm or greater and 200 μm or less, for example.

As shown in FIG. 2, the two second suspending-lead portions 222 extend from the opposite ends of the second pad portion 221 in the second direction y. Each of the two second suspending-lead portions 222 includes a covered portion 222A and an exposed portion 222B. The covered portion 222A is connected to the second pad portion 221 and covered with the sealing resin 50. The covered portion 222A includes a section extending in the first direction x. The exposed portion 222B is connected to the covered portion 222A and exposed from the sealing resin 50. As viewed in the thickness direction z, the exposed portion 222B extends in the first direction x. As viewed in the second direction y, the exposed portion 222B is bent into a gull wing shape (see FIGS. 2 and 4). The surface of the exposed portion 222B may be plated with tin (Sn), for example.

As shown in FIGS. 6 and 7, the support member 23 supports the insulating element 13 mounted thereon. As shown in FIGS. 2 and 6, in the semiconductor device Al, the support member 23 is located between the first die pad 21 and the second die pad 22 in the first direction x. In addition, the support member 23 is located away from either end of the sealing resin 50 in the second direction y. The support member 23 is covered with the sealing resin 50.

As shown in FIG. 8, in the semiconductor device A1, the support member 23 is in contact with the first pad portion 211 of the first die pad 21 and the second pad portion 221 of the second die pad 22 at the opposite ends in the first direction x. That is, the support member 23 fills out the space between the first pad portion 211 and the second pad portion 221. In addition, the support member 23 is in contact with the sealing resin 50 at either end in the thickness direction z. That is, the support member 23 of the semiconductor device Al is supported by the first die pad 21, the second die pad 22 and the sealing resin 50.

As shown in FIGS. 6 and 7, the support member 23 has the mounting surface 23A facing in the thickness direction z. The insulating element 13 is mounted on the mounting surface 23A. As shown in FIG. 8, the support member 23 has a thickness t that is less than the thickness T of each of the first pad portion 211 of the first die pad 21 and the second pad portion 221 of the second die pad 22. The mounting surface 23A is continuous with the first mounting surface 211A of the first pad portion 211 and the second mounting surface 221A of the second pad portion 221.

As shown in FIGS. 6 and 7, at least a portion of the support member 23 is an insulating portion 231. The insulating portion 231 is made of a material containing a resin, which is an epoxy resin in one example. In the semiconductor device A1, the entire portion of the support member 23 is the insulating portion 231.

As shown in FIGS. 6 and 7, the bonding layer 29 is located between the mounting surface 23A of the support member 23 and the insulating element 13. The bonding layer 29 bonds the insulating element 13 to the mounting surface 23A. The bonding layer 29 is electrically insulating. The bonding layer 29 is made of a material containing an epoxy resin, for example.

As shown in FIGS. 1 and 2, the first terminals 31 are located on a first side in the first direction x. More specifically, the first terminals 31 are located on the side opposite the second pad portion 221 of the second die pad 22 with respect to the first pad portion 211 of the first die pad 21 in the first direction x. The first terminals 31 are arranged along the second direction y. At least one of the first terminals 31 is electrically connected to the first semiconductor element 11 via a third wire 43. The first terminals 31 include a plurality of first inner terminals 31A and two first outer terminals 31B. The two first outer terminals 31B are spaced apart in the second direction y, with the plurality of first inner terminals 31A between them. In the second direction y, each of the two first suspending-lead portions 212 of the first die pad 21 is located between one of the first outer terminals 31B and the first inner terminal 31A nearest to the one first outer terminal 31B.

As shown in FIGS. 2 and 6, each first terminal 31 includes a covered portion 311 and an exposed portion 312. The covered portion 311 is covered with the sealing resin 50. The covered portion 311 of each first outer terminal 31B has a length in the first direction x that is greater than the length of the covered portion 311 of each first inner terminal 31A in the first direction x.

As shown in FIGS. 2 and 6, the exposed portion 312 is connected to the covered portion 311 and exposed from the sealing resin 50. As viewed in the thickness direction z, the exposed portion 312 extends in the first direction x. As viewed in the second direction y, the exposed portion 312 is bent into a gull wing shape. The exposed portion 312 has a shape similar to that of the exposed portion 212B of each first suspending-lead portion 212 of the first die pad 21. The surface of the exposed portion 312 may be plated with tin, for example.

As shown in FIGS. 1 and 2, the second terminals 32 are located on a second side in the first direction x. More specifically, the second terminals 32 are located on the side opposite the first terminals 31 in the first direction x with respect to the first pad portion 211 of the first die pad 21. The second terminals 32 are arranged side by side in the second direction y. At least one of the second terminals 32 is electrically connected to the second semiconductor element 12 via a fourth wire 44. The second terminals 32 include a plurality of second inner terminals 32A and two second outer terminals 32B. The two second outer terminals 32B are spaced apart in the second direction y, with the plurality of second inner terminals 32A between them. In the second direction y, each of the two second suspending-lead portions 222 of the second die pad 22 is located between one of the second outer terminals 32B and the second inner terminal 32A nearest to the one second outer terminal 32B.

As shown in FIGS. 2 and 6, each second terminal 32 includes a covered portion 321 and an exposed portion 322. The covered portion 321 is covered with the sealing resin 50. The covered portion 321 of each second outer terminal 32B has a length in the first direction x that is greater than the length of the covered portion 321 of each second inner terminal 32A in the first direction x.

As shown in FIGS. 2 and 6, the exposed portion 322 is connected to the covered portion 321 and exposed from the sealing resin 50. As viewed in the thickness direction z, the exposed portion 322 extends in the first direction x. As shown in FIG. 3, the exposed portion 322 is bent into a gull wing shape as viewed in the second direction y. The exposed portion 322 has a shape similar to that of the exposed portion 222B of each second suspending-lead portion 222 of the second die pad 22. The surface of the exposed portion 322 may be plated with tin, for example.

The first wires 41, the second wires 42, the third wires 43 and the fourth wires 44 together with the conductive members 20 form conductive paths necessary for the first semiconductor element 11, the second semiconductor element 12 and the insulating element 13 to perform their functions.

As shown in FIGS. 2 and 6, first wires 41 are bonded to first electrodes 111 of the first semiconductor element 11 and also to the covered portions 311 of first terminals 31. This electrically connects at least one of the first terminals 31 to the first semiconductor element 11. Additionally, at least one of the first wires 41 is bonded to a first electrode 111 and also to the covered portion 212A of one of the two first suspending-lead portions 212 of the first die pad 21. This electrically connects the first semiconductor element 11 to at least one of the first suspending-lead portions 212. The at least one first suspending-lead portion 212 serves as the ground terminal of the first semiconductor element 11. The first wires 41 contain gold (Au). In another example, the first wires 41 may contain copper.

As shown in FIGS. 2 and 6, second wires 42 are bonded to second electrodes 121 of the second semiconductor element 12 and also to the covered portions 321 of second terminals 32. This electrically connects at least one of the second terminals 32 to the second semiconductor element 12. Additionally, at least one of the second wires 42 is bonded to a second electrode 121 and also to the covered portion 222A of one of the two second suspending-lead portions 222 of the second die pad 22. This electrically connects the second semiconductor element 12 to at least one of the two second suspending-lead portions 222. The at least one second suspending-lead portion 222 serves as the ground terminal of the second semiconductor element 12. The second wires 42 contain gold. In another example, the second wires 42 may contain copper.

As shown in FIGS. 2 and 6, each third wire 43 is bonded to a first relay electrode 131 of the insulating element 13 and also to a first electrode 111 of the first semiconductor element 11. This electrically connects the first semiconductor element 11 and the insulating element 13 with each other. The third wires 43 are arranged side by side in the second direction y. The third wires 43 extend across the boundary between the first pad portion 211 of the first die pad 21 and the support member 23. The third wires 43 contain gold.

As shown in FIGS. 2 and 6, each fourth wire 44 is bonded to a second relay electrode 132 of the insulating element 13 and also to a second electrode 121 of the second semiconductor element 12. This electrically connects the second semiconductor element 12 and the insulating element 13 with each other. The fourth wires 44 are arranged side by side in the second direction y. The fourth wires 44 extend across the boundary between the support member 23 and the second pad portion 221 of the second die pad 22. The fourth wires 44 contain gold.

As shown in FIG. 1, the sealing resin 50 covers the first semiconductor element 11, the second semiconductor element 12, the insulating element 13 and at least a portion of each conductive member 20. The sealing resin 50 also covers the first wires 41, the second wires 42, the third wires 43 and the fourth wires 44. The sealing resin 50 is electrically insulating. The sealing resin 50 is made of a material containing an epoxy resin, for example. The sealing resin 50 is rectangular as viewed in the thickness direction z.

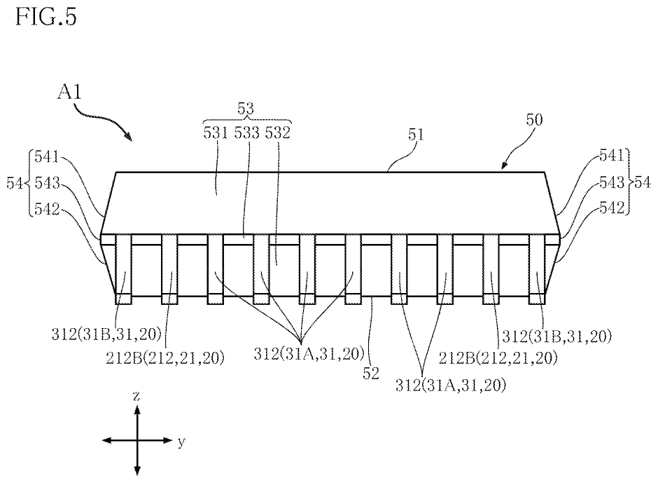

As shown in FIGS. 3 and 5, the sealing resin 50 has a top surface 51, a bottom surface 52, a pair of first side surfaces 53 and a pair of second side surfaces 54.

As shown in FIGS. 3 and 5, the top surface 51 and the bottom surface 52a are spaced apart from each other in the thickness direction z, facing away from each other in the thickness direction z. Each of the top surface 51 and the bottom surface 52 is flat (or substantially flat).

As shown in FIGS. 3 and 5, the first side surfaces 53 are connected to the top surface 51 and the bottom surface 52 and spaced apart from each other in the first direction x. The exposed portions 212B of the two first suspending-lead portions 212 of the first die pad 21 and the exposed portions 312 of the first terminals 31 are exposed from the first side surface 53 located on the first side in the first direction x. The exposed portions 212B of the two second suspending-lead portions 222 of the second die pad 22 and the exposed portions 322 of the second terminals 32 are exposed from the first side surface 53 located on the second side in the first direction x.

As shown in FIGS. 3 and 5, each first side surface 53 includes a first upper portion 531, a first lower portion 532 and a first middle portion 533. The first upper portion 531 is connected to the top surface 51 at one end in the thickness direction z and to the first middle portion 533 at the other end in the thickness direction z. The first upper portion 531 is inclined relative to the top surface 51. The first lower portion 532 is connected to the bottom surface 52 at one end in the thickness direction z and to the first middle portion 533 at the other end in the thickness direction z. The first lower portion 532 is inclined relative to the bottom surface 52. The first middle portion 533 is connected to the first upper portion 531 at one end in the thickness direction z and to the first lower portion 532 at the other end in the thickness direction z. The first middle portion 533 has the in-plane direction parallel to the thickness direction z and the second direction y. As viewed in the thickness direction z, the first middle portion 533 is located outside the top surface 51 and the bottom surface 52. The exposed portions 212B of the two first suspending-lead portions 212 of the first die pad 21, the exposed portions 222B of the two second suspending-lead portions 222 of the second die pad 22, the exposed portions 312 of the first terminals 31 and the exposed portions 322 of the second terminals 32 are exposed from the first middle portions 533 of the first side surfaces 53.

As shown in FIGS. 3 and 5, the second side surfaces 54 are connected to the top surface 51 and the bottom surface 52 and spaced apart from each other in the second direction y. As shown in FIG. 1, the first die pad 21, the second die pad 22, the first terminals 31 and the second terminals 32 are located away from either of the second side surfaces 54.

As shown in FIGS. 3 and 5, each second side surface 54 includes a second upper portion 541, a second lower portion 542 and a second middle portion 543. The second upper portion 541 is connected to the top surface 51 at one end in the thickness direction z and to the second middle portion 543 at the other end in the thickness direction z. The second upper portion 541 is inclined relative to the top surface 51. The second lower portion 542 is connected to the bottom surface 52 at one end in the thickness direction z and to the second middle portion 543 at the other end in the thickness direction z. The second lower portion 542 is inclined relative to the bottom surface 52. The second middle portion 543 is connected to the second upper portion 541 at one end in the thickness direction z and to the second lower portion 542 at the other end in the thickness direction z. The second middle portion 543 has the in-plane direction parallel to the thickness direction z and the first direction x. As viewed in the thickness direction z, the second middle portion 543 is located outside the top surface 51 and the bottom surface 52.

Generally, the motor driver circuit of an inverter device includes a half-bridge circuit including a low-side (low-potential side) switching element and a high-side (high-potential side) switching element. The following description is directed to an example in which the switching elements are MOSFETs. In such an example, the source of the low-side switching element and the gate driver that drives the low-side switching element both have a reference potential held at ground. In contrast, the source of the high-side switching element and the gate driver that drives the high-side switching element both have a reference potential corresponding to the potential at the output node of the half-bridge circuit. The potential at the output node varies in response to the switching of the high-side switching element and the low-side switching element, so that the reference potential of the gate driver for the high-side switching element varies as well. During the time the high-side switching element is ON, the reference potential is equal to the voltage applied to the drain of the switching element (e.g., about 600 V or higher). In the semiconductor device A1, the first semiconductor element 11 and the second semiconductor element 12 have isolated grounds. Thus, when the semiconductor device A1 is used as a gate driver for driving a high-side switching element, the ground of the second semiconductor element 12 can be subjected to a transient voltage equal to the voltage applied to the drain of the high-side switching element.

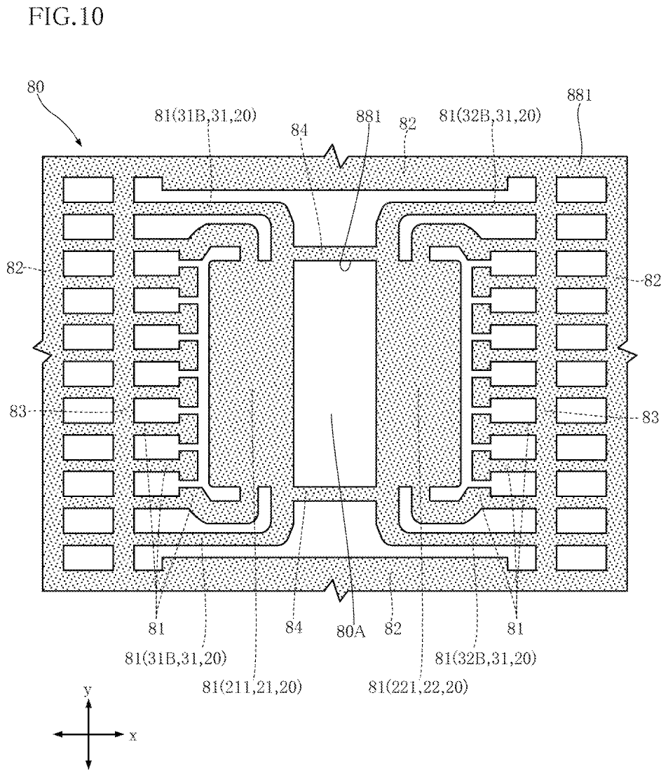

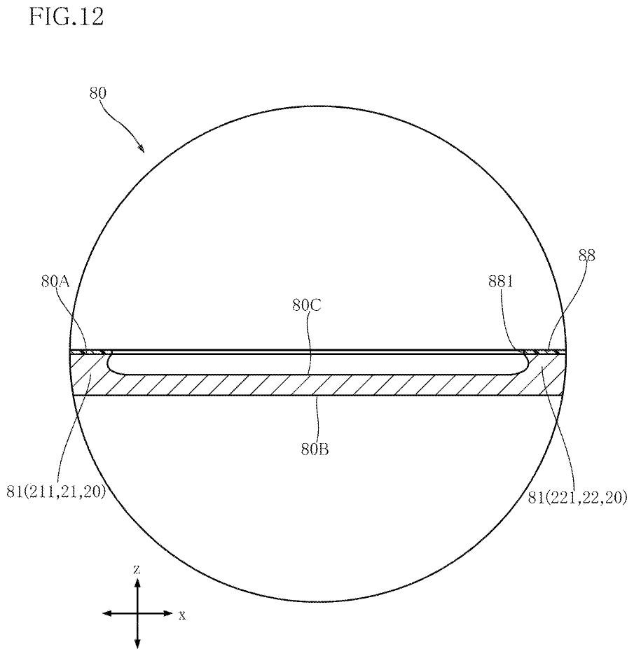

Next, with reference to FIGS. 10 to 15, the following describes one example of a method of forming the support member 23 of the semiconductor device A1. Note that the sections shown in FIGS. 12 to 14 correspond in position to the section shown in FIG. 8.

First, a first resist layer 88 is deposited on the lead frame 80 and patterned by photolithography as shown in FIG. 10. In FIG. 10, the first resist layer 88 is shaded with dots. As shown in FIG. 12, the lead frame 80 has an obverse surface 80A and a reverse surface 80B facing away from each other in the thickness direction z. The first resist layer 88 covers the obverse surface 80A. The first resist layer 88 has a first opening 881. The first opening 881 is formed above the region in the lead frame 80e where the support member 23 will be formed. The first opening 881 exposes the obverse surface 80A.

As shown in FIG. 10, the lead frame 80 includes a plurality of leads 81, a frame 82, two first dam bars 83 and 80, two second dam bars 84. Of these portions of the lead frame the leads 81 correspond to the conductive members 20. The frame 82 is a portion surrounding the leads 81. Each lead 81 is connected to either of the two segments of the frame 82 spaced apart from each other in the first direction x. The two first dam bars 83 are spaced apart from each other in the first direction x and extend in the second direction y. One of the two first dam bars 83 is connected to the leads 81 corresponding to the first die pad 21 and the first terminals 31. The other of the two first dam bars 83 is connected to the leads 81 corresponding to the second die pad 22 and the second terminals 32.

As shown in FIG. 10, the two second dam bars 84 are located adjacent to the first opening 881 formed in the first resist layer 88 as viewed in the thickness direction z. The two second dam bars 84 are spaced apart from each other in the second direction y and extend in the first direction x. The two second dam bars 84 are connected to the opposite ends in the second direction y of each of the lead 81 corresponding to the first pad portion 211 of the first die pad 21 and the lead 81 corresponding to the second pad portion 221 of the second die pad 22.

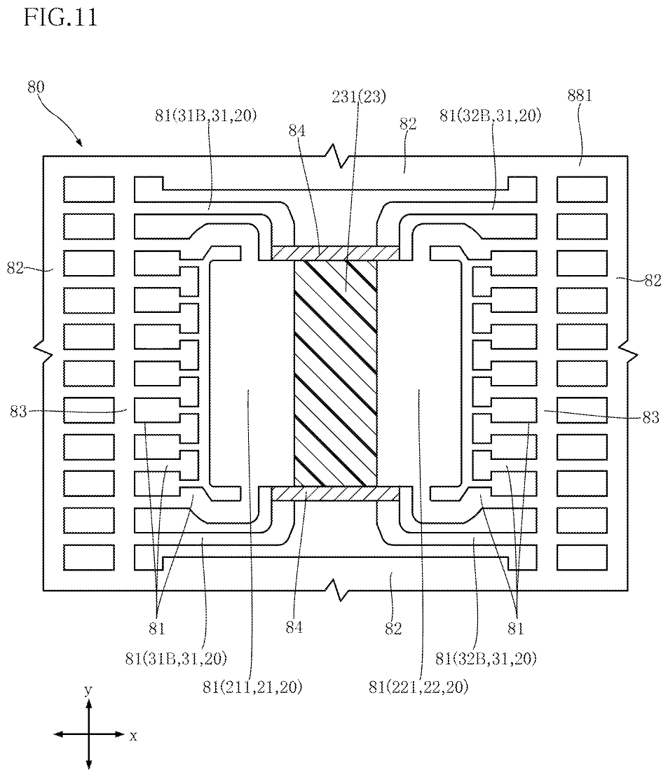

Next, as shown in FIG. 11, the insulating portion 231 of the support member 23 is formed. In FIG. 11, the hatched areas indicate the insulating portion 231 and the two second dam bars 84. The insulating portion 231 is surrounded by the lead 81 corresponding to the first pad portion 211 of the first die pad 21, the lead 81 corresponding to the second pad portion 221 of the second die pad 22, and the two second dam bars 84. The insulating portion 231 is formed through the processes shown in FIGS. 12 to 14 as follows.

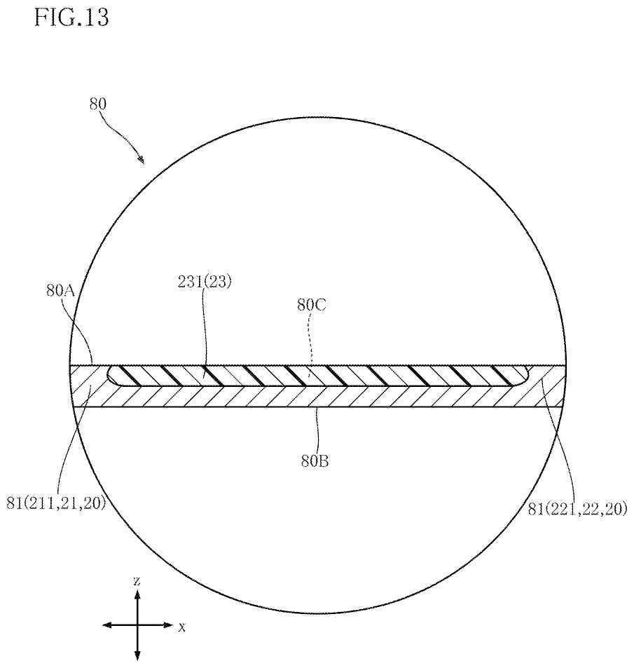

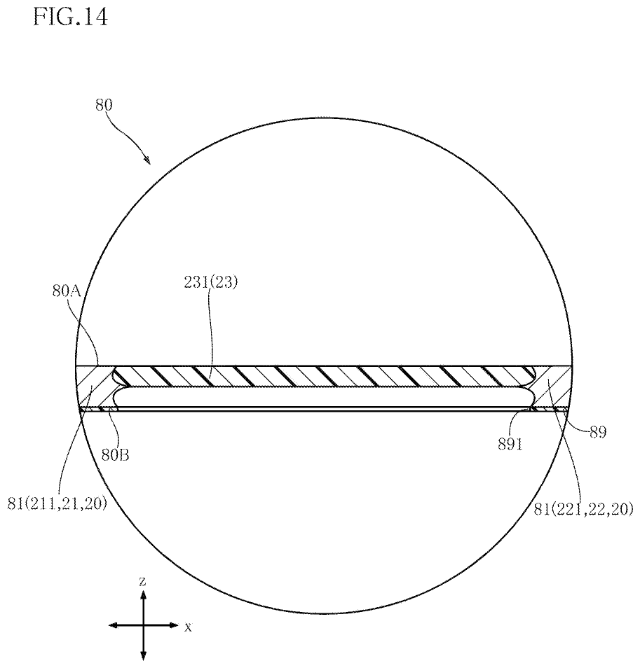

In the FIG. 12, half-etching is applied to the obverse surface 80A of the lead frame 80 exposed through the first opening 881 in the first resist layer 88. As a result, a recess 80C that is recessed in the thickness direction z is formed in the obverse surface 80A of the lead frame 80. Next, as shown in FIG. 13, the insulating portion 231 is formed by molding. The insulating portion 231 is formed to fill the recess 80C. Next, as shown in FIG. 14, a second resist layer 89 is deposited on the reverse surface 80B of the lead frame 80 and patterned by photolithography to form a second opening 891. Then, etching is applied to the reverse surface 80B exposed through the second opening 891. As viewed in the thickness direction z, the second opening 891 is identical in position and size to the first opening 881 in the first resist layer 88. In the state shown in FIG. 14, the portion of the lead frame 80 overlapping with the insulating portion 231 as viewed in the thickness direction z has been removed, so that the insulating portion 231 is exposed on the reverse surface 80B. Through the above processes, the insulating portion 231 is formed.

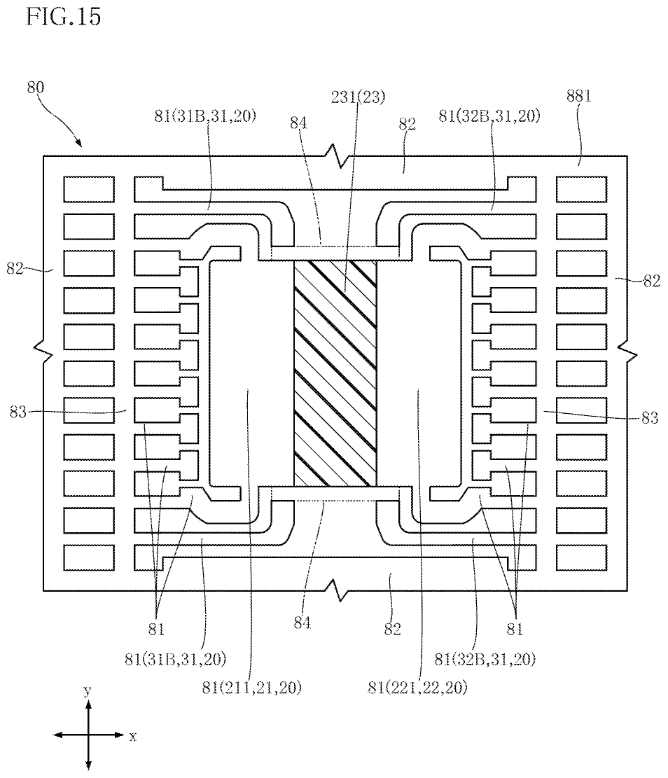

Lastly, as shown in FIG. 15, the two second dam bars 84 are removed by etching. As a result, the opposite ends of the insulating portion 231 in the first direction x are supported by the lead 81 corresponding to the first pad portion 211 of the first die pad 21 and the lead 81 corresponding to the second pad portion 221 of the second die pad 22. Through the above processes, the support member 23 of the semiconductor device A1 is obtained.

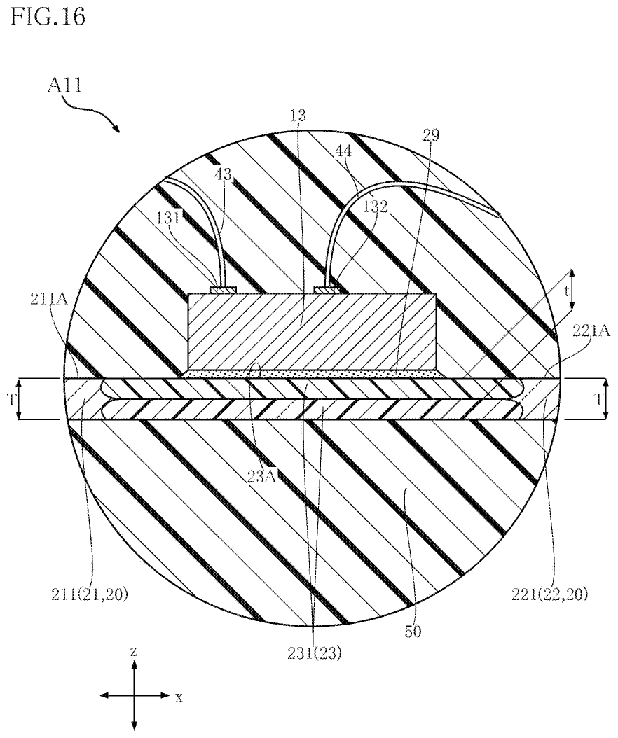

Next, with reference to FIG. 16, the following describes a semiconductor device A11 that is a variation of the semiconductor device A1. The section shown in FIG. 16 corresponds in position to the section shown in FIG. 8.

As shown in FIG. 16, the support member 23 of this variation includes two layers laminated in the thickness direction z. The thickness t of the support member 23 is equal to or greater than the thickness T of each of the first pad portion 211 of the first die pad 21 and the second pad portion 221 of the second die pad 22 alone. The mounting surface 23A of the support member 23 is continuous with the first mounting surface 211A of the first pad portion 211 and the second mounting surface 221A of the second pad portion 221. That is, the support member 23 fills the space between the first pad portion 211 and the second pad portion 221 throughout the length in the thickness direction z.

The support member 23 of the semiconductor device All is obtained by forming an additional insulating portion 231 through a molding process similar to that shown in FIG. 13, after the process of etching the reverse surface 80B of the lead frame 80 exposed through the second opening 891 in the second resist layer 89 as shown in FIG. 14.

The following describes advantages of the semiconductor device A1.

The semiconductor device A1 includes: a plurality of conductive members 20 including a first die pad 21 and a second die pad 22 spaced apart from each other in the first direction x; a first semiconductor element 11; a second semiconductor element 12; an insulating element 13 that insulates the first semiconductor element 11 and the second semiconductor element 12 from each other; and a sealing resin 50. The semiconductor device A1 also includes a support member 23 on which the insulating element 13 is mounted. The support member 23 includes an insulating portion 231 that contains a resin. The support member 23 is supported by at least one of the first die pad 21, the second die pad 22 and the sealing resin 50. With this configuration, the support member 23 electrically floats relative to the first die pad 21 and the second die pad 22. This prevents the flow of charge carriers from the first semiconductor element 11 and the second semiconductor element 12 into the insulating element 13. The semiconductor device Al can therefore improve the dielectric strength between the semiconductor elements (the first semiconductor element 11 and the second semiconductor element 12) and the insulating element 13.

In the semiconductor device Al, the support member 23 is located between the first die pad 21 and the second die pad 22 in the first direction x. This allows both the first semiconductor element 11 and the second semiconductor element 12 to be located at a relatively long minimum distance away from the insulating element 13. Hence, the travel distance is longer for the charge carriers to reach the insulating element 13 from the first semiconductor element 11 or the second semiconductor element 12. This is preferable for further improving the dielectric strength between the first semiconductor element 11 or the second semiconductor element 12 and the insulating element 13. In the semiconductor device A1, in addition, the entire portion of the support member 23 is composed of the insulating portion 231. This is effective for more reliably prevent the flow of charge carriers.

The semiconductor device Al further includes a bonding layer 29 between the support member 23 and the insulating element 13. Preferably, the bonding layer 29 is electrically insulating. This is effective for preventing the flow of charge carriers from the upper surface of the support member 23 (the mounting surface 23A) to the lower surface of the insulating element 13 facing the upper surface.

The insulating element 13 includes a first transmitting/receiving portion 133, a second transmitting/receiving portion 134 and a relay portion 135. In the thickness direction z, the relay portion 135 is located closer to the support member 23 than the first transmitting/receiving portion 133 and the second transmitting/receiving portion 134. This configuration serves to reduce the potential difference developed in the insulating element 13, between the first transmitting/receiving portion 133 and the relay portion 135, as well as between the second transmitting/receiving portion 134 and the relay portion 135. Consequently, the dielectric strength of the insulating element 13 is improved. In addition, this configuration also serves to reduce the potential difference between the upper surface of the support member 23 (the mounting surface 23A) and the lower surface of the insulating element 13 facing the upper surface. This is effective for improving the dielectric strength between the support member 23 and the insulating element 13.

In the semiconductor device A1, a portion of each conductive member 20 is exposed from either of the first side surfaces 53 of the sealing resin 50. This configuration is made possible by the two first suspending-lead portions 212 of the first die pad 21 exposed from the sealing resin 50 on the first side in the first direction x and the two second suspending-lead portions 222 of the second die pad 22 exposed from the sealing resin 50 on the second side in the first direction x. This configurator makes it possible to arrange the conductive members 20 away from the second side surfaces 54 of the sealing resin 50, thereby improving the dielectric strength of the semiconductor device A1.

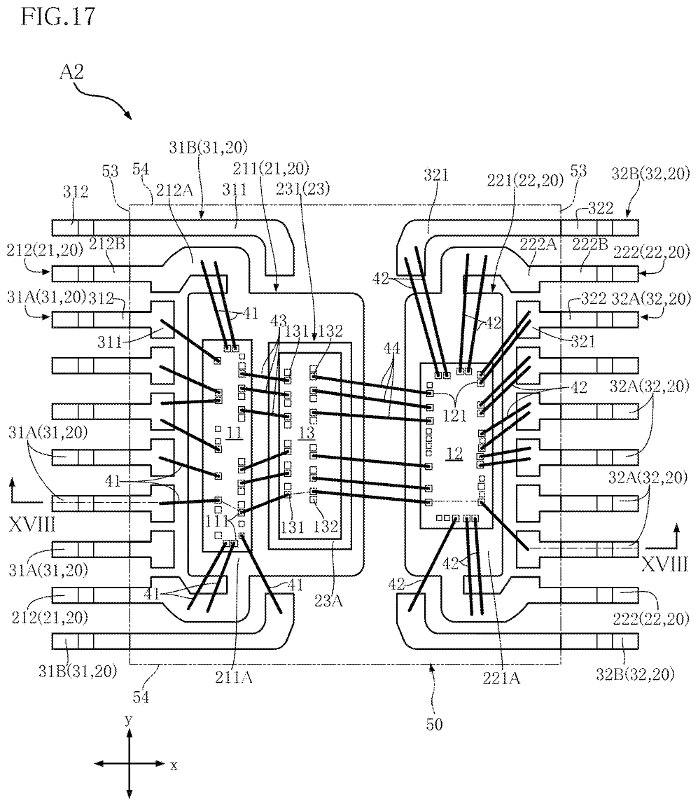

With reference to FIGS. 17 to 19, the following describes a semiconductor device A2 according to a second embodiment of the present disclosure. In these figures, the identical or similar elements to those of the semiconductor device A1 described above are denoted by the same reference signs, and descriptions of such elements are omitted. For the convenience of description, FIG. 17 shows the sealing resin 50 as transparent and indicates the sealing resin 50 with imaginary lines.

The semiconductor device A2 differs from the semiconductor device A1 described above in the configuration of the first die pad 21 and the support member 23.

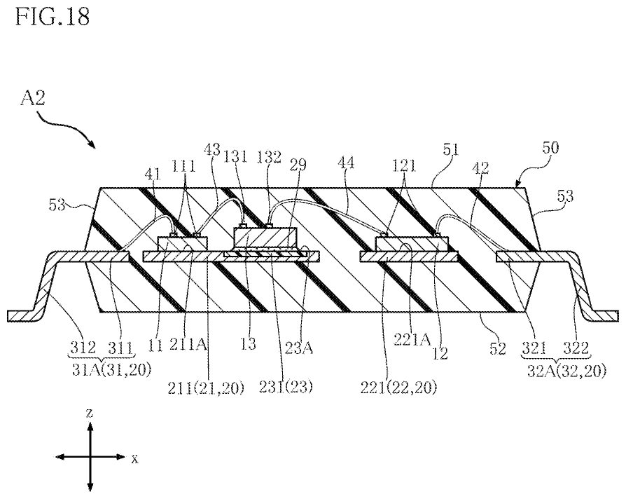

As shown in FIGS. 17 and 18, the support member 23 overlaps with the first pad portion 211 of the first die pad 21 as viewed in the thickness direction z. The support member 23 is in contact with the first pad portion 211. In the semiconductor device A2, the entire portion of the support member 23 is the insulating portion 231.

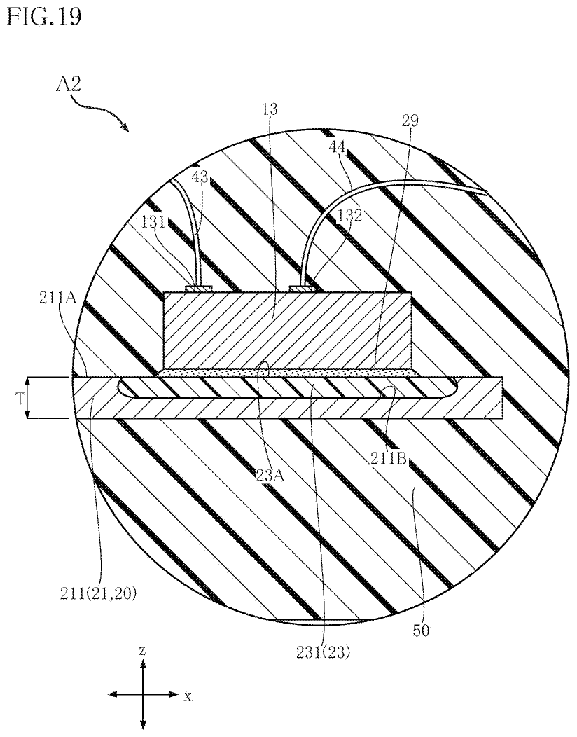

As shown in FIG. 19, the first pad portion 211 of the first die pad 21 includes a recess 211B that is recessed in the thickness direction z from the first mounting surface 211A. The support member 23 is accommodated in the recess 211B. Hence, the support member 23 of the semiconductor device A2 is supported by the first die pad 21.

As shown in FIGS. 17 and 18, the third wires 43 are included in the region of the first pad portion 211 of the first die pad 21. The fourth wires 44 extend across the space between the first pad portion 211 and the second pad portion 221 of the second die pad 22.

Next, the following describes one example of a method of forming the support member 23 of the semiconductor device A2. First, in the process shown in FIG. 10, a first resist layer 88 is deposited on the obverse surface 80A of the lead frame and patterned to form a first opening 881 above the lead 81 that corresponds to the first pad portion 211 of the first die pad 21. The lead frame 80 is processed in advance to form the lead 81 corresponding to the first die pad 21 and the lead 81 corresponding to the second die pad 22 that are spaced apart from each other in the first direction x. Next, in the process shown in FIG. 12, half-etching is applied to the obverse surface 80A exposed through the first opening 881, thereby forming a recess 211B in the first pad portion 211. Next, in the process shown in FIG. 13, the insulating portion 231 of the support member 23 is formed by molding. The insulating portion 231 thus formed is accommodated in the recess 211B. Through the above processes, the support member 23 of the semiconductor device A2 is obtained.

The following describes advantages of the semiconductor device A2.

The semiconductor device A2 includes: a plurality of conductive members 20 including a first die pad 21 and a second die pad 22 spaced apart from each other in the first direction x; a first semiconductor element 11; a second semiconductor element 12; an insulating element 13 that insulates the first semiconductor element 11 and the second semiconductor element 12 from each other; and a sealing resin 50. The semiconductor device A2 also includes a support member 23 on which the insulating element 13 is mounted. The support member 23 includes an insulating portion 231 that contains a resin. The support member 23 is supported by at least one of the first die pad 21, the second die pad 22 and the sealing resin 50. The semiconductor device A2 can therefore improve the dielectric strength between the semiconductor elements (the first semiconductor element 11 and the second semiconductor element 12) and the insulating element 13. In addition, the semiconductor device A2 has a configuration in common with the semiconductor device A1, thereby achieving the same effect as the semiconductor device A1.

In the semiconductor device A2, the first pad portion 211 of the first die pad 21 has the recess 211B that is recessed in the thickness direction z. The support member 23 is accommodated in the recess 211B. The method of forming the support member 23 of the semiconductor device A2 does not require the process of etching the reverse surface 80B of the lead frame 80 exposed through the second opening 891 in the second resist layer 89 as shown in FIG. 14 and the process of removing the two second dam bars 84 as shown in FIG. 15. The support member 23 of this embodiment can be formed with fewer man-hours than the support member 23 of the semiconductor device A1.

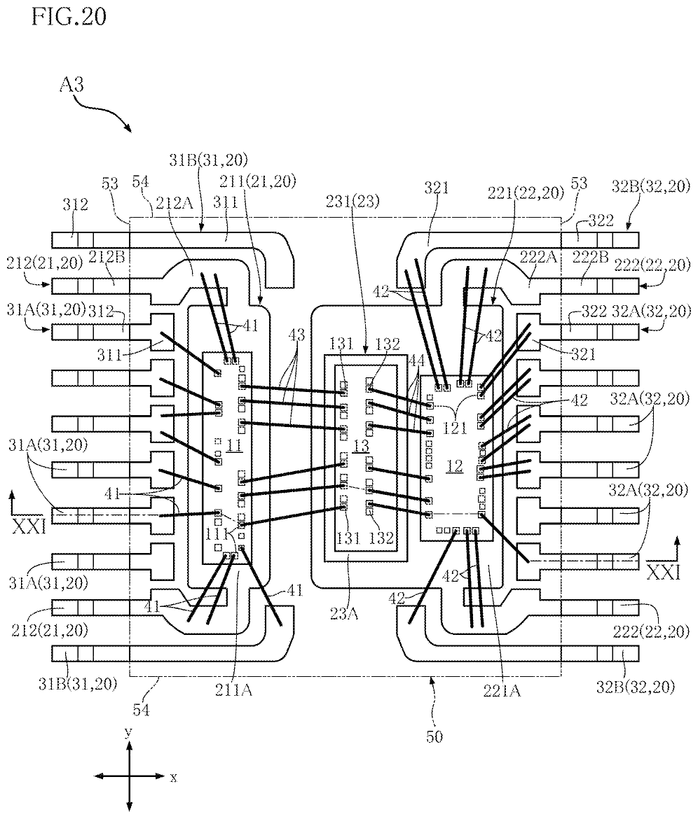

With reference to FIGS. 20 to 22, the following describes a semiconductor device A3 according to a third embodiment of the present disclosure. In these figures, the identical or similar elements to those of the semiconductor device A1 described above are denoted by the same reference signs, and descriptions of such elements are omitted. For the convenience of description, FIG. 20 shows the sealing resin 50 as transparent and indicates the sealing resin 50 with imaginary lines.

The semiconductor device A3 differs from the semiconductor device Al described above in the configuration of the second die pad 22 and the support member 23.

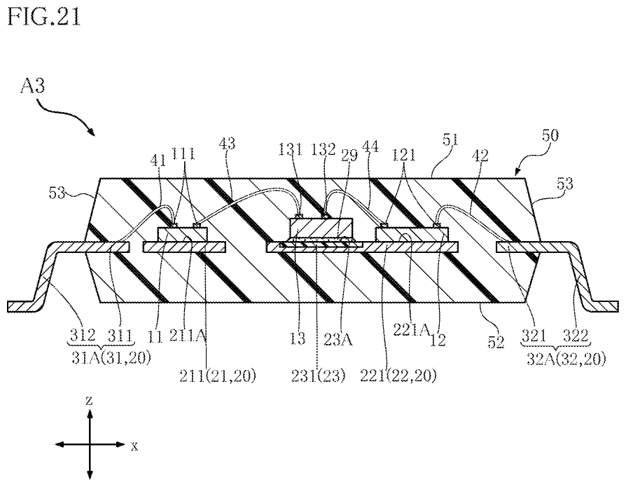

As shown in FIGS. 20 and 21, the support member 23 overlaps with the second pad portion 221 of the second die pad 22 as viewed in the thickness direction z. The support member 23 is in contact with the second pad portion 221. In the semiconductor device A3, the entire portion of the support member 23 is the insulating portion 231.

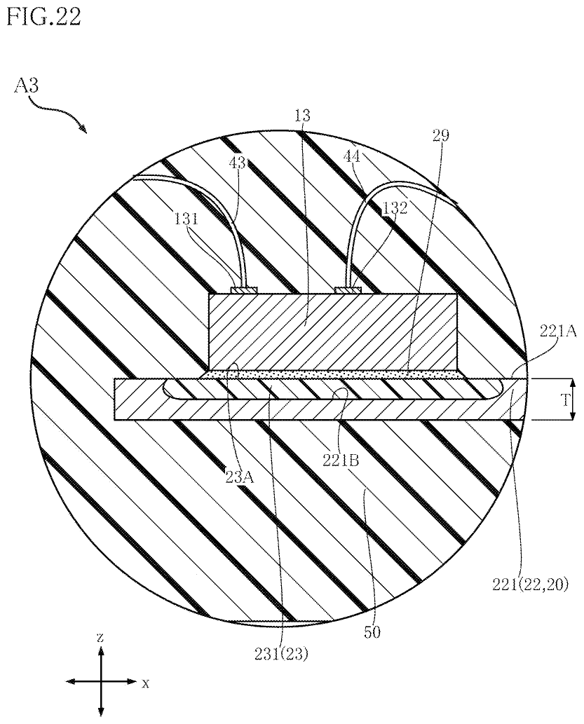

As shown in FIG. 22, the second pad portion 221 of the second die pad 22 includes a recess 221B that is recessed in the thickness direction z from the second mounting surface 221A. The support member 23 is accommodated in the recess 221B. Hence, the support member 23 of the semiconductor device A3 is supported by the second die pad 22.

As shown in FIGS. 20 and 21, the third wires 43 extend across the space between the first pad portion 211 of the first die pad 21 and the second pad portion 221 of the second die pad 22. The fourth wires 44 are included in the region of the second pad portion 221.

Next, the following describes one example of a method of forming the support member 23 of the semiconductor device A3. First, in the process shown in FIG. 10, a first resist layer 88 is deposited on the obverse surface 80A of the lead frame 80 and patterned to form a first opening 881 above the lead 81 that corresponds to the second pad portion 221 of the second die pad 22. The lead frame 80 is processed in advance to form the lead 81 corresponding to the first die pad 21 and the lead 81 corresponding to the second die pad 22 that are spaced apart from each other in the first direction x. Next, in the process shown in FIG. 12, half-etching is applied to the obverse surface 80A exposed through the first opening 881, thereby forming a recess 221B in the second pad portion 221. Next, in the process shown in FIG. 13, the insulating portion 231 of the support member 23 is formed by molding. The insulating portion 231 thus formed is accommodated in the recess 221B. Through the above processes, the support member 23 of the semiconductor device A3 is obtained.

The following describes advantages of the semiconductor device A3.

The semiconductor device A3 includes: a plurality of conductive members 20 including a first die pad 21 and a second die pad 22 spaced apart from each other in the first direction x; a first semiconductor element 11; a second semiconductor element 12; an insulating element 13 that insulates the first semiconductor element 11 and the second semiconductor element 12 from each other; and a sealing resin 50. The semiconductor device A3 also includes a support member 23 on which the insulating element 13 is mounted. The support member 23 includes an insulating portion 231 that contains a resin. The support member 23 is supported by at least one of the first die pad 21, the second die pad 22 and the sealing resin 50. The semiconductor device A3 can therefore improve the dielectric strength between the semiconductor elements (the first semiconductor element 11 and the second semiconductor element 12) and the insulating element 13. In addition, the semiconductor device A3 has a configuration in common with the semiconductor device Al, thereby achieving the same effect as the semiconductor device A1.

In the semiconductor device A3, the second pad portion 221 of the second die pad 22 has the recess 221B that is recessed in the thickness direction z. The support member 23 is accommodated in the recess 221B. The support member 23 of the semiconductor device A3 can be formed by a method similar to the method of forming the support member 23 of the semiconductor device A2 described above. Hence, the support member 23 of this embodiment can be formed with fewer man-hours than the support member 23 of the semiconductor device A1.

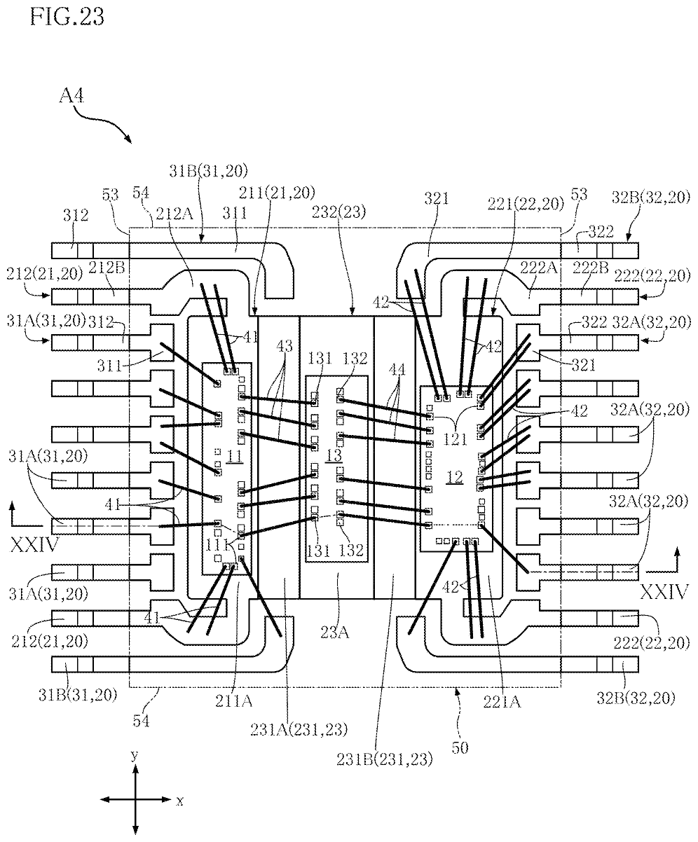

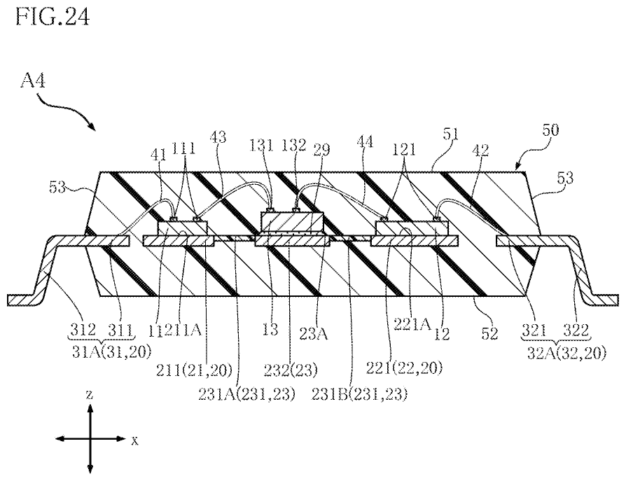

With reference to FIGS. 23 to 24, the following describes a semiconductor device A4 according to a fourth embodiment of the present disclosure. In these figures, the identical or similar elements to those of the semiconductor device A1 described above are denoted by the same reference signs, and descriptions of such elements are omitted. For the convenience of description, FIG. 23 shows the sealing resin 50 as transparent and indicates the sealing resin 50 in imaginary lines.

The semiconductor device A4 differs from the semiconductor device A1 described above in the configuration of the support member 23.

As shown in FIGS. 23 and 24, the support member 23 includes a metal portion 232 supported by the insulating portion 231. The metal portion 232 is located between the first die pad 21 and the second die pad 22 in the first direction x. The insulating element 13 is mounted on the mounting surface 23A of the metal portion 232.

The metal portion 232 of the support member 23 corresponds to a portion of the lead frame 80 shown in FIG. 10. That is, the metal portion 232 is formed from the lead frame 80 as with the conductive members 20. The metal portion 232 is identical in composition to the conductive members 20. The metal portion 232 has a thickness that is equal to the thickness T of each of the first pad portion 211 of the first die pad 21 and the second pad portion 221 of the second die pad 22 shown in FIG. 8.

As shown in FIGS. 23 and 24, the insulating portion 231 of the support member 23 includes a first portion 231A and a second portion 231B located with the metal portion 232 in between. In the semiconductor device A4, the first portion 231A and the second portion 231B are spaced apart from each other in the first direction x. The first portion 231A is in contact with the first pad portion 211 of the first die pad 21, whereas the second portion 231B is in contact with the second pad portion 221 of the second die pad 22. That is, the support member 23 of the semiconductor device A4 is supported by the first die pad 21, the second die pad 22 and the sealing resin 50. Then, the metal portion 232 is supported by the first portion 231A, the second portion 231B and the sealing resin 50. The third wires 43 extend across the first portion 231A, and the fourth wires 44 extend across the second portion 231B.

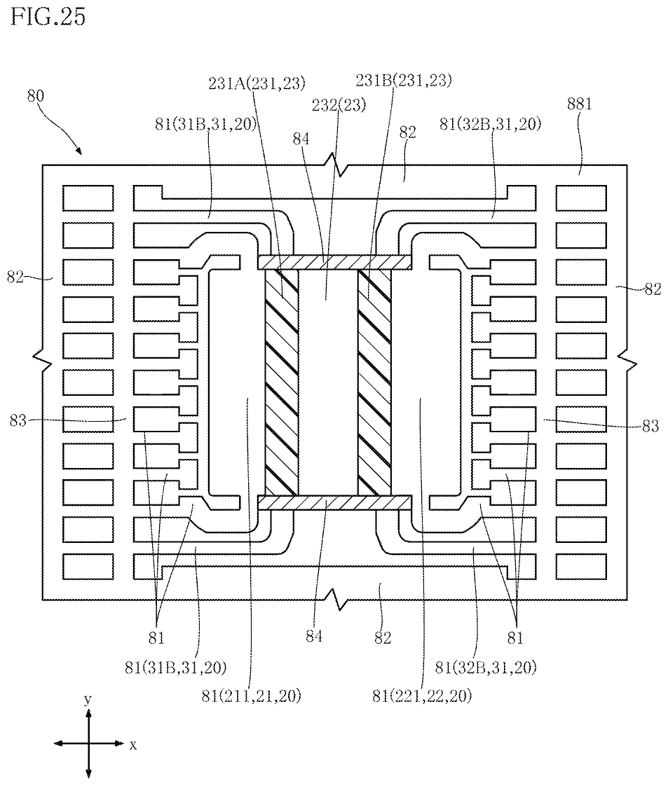

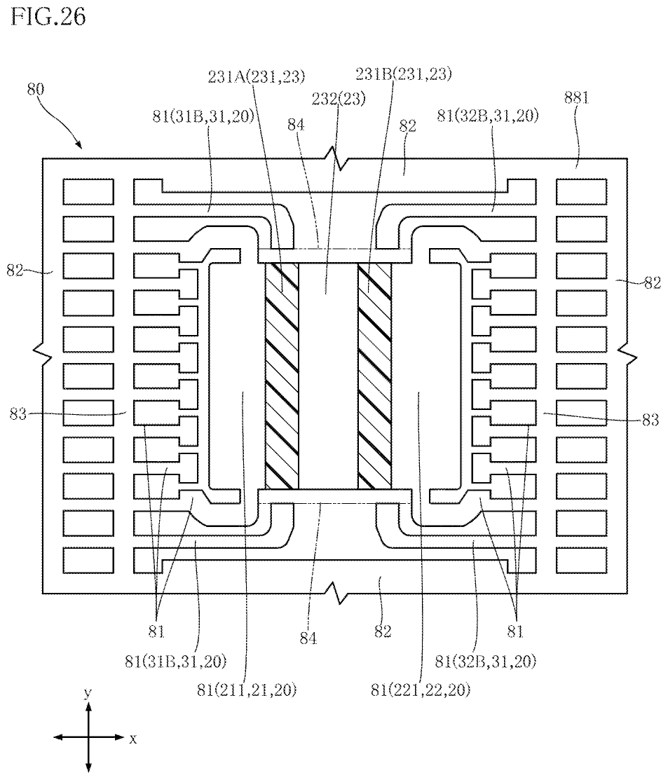

Next, with reference to FIGS. 25 and 26, the following describes one example of a method of forming the support member 23 of the semiconductor device A4.

FIG. 25 shows the lead frame 80 after the insulating portion 231 of the support member 23 is formed. The insulating portion 231 is formed through the processes similar to those shown in FIGS. 12 to 14 for forming the insulating portion 231 of the semiconductor device A1. In FIG. 25, the hatched areas indicate the first portion 231A and the second portion 231B of the insulating portion 231 and the two second dam bars 84. The metal portion 232 of the support member 23 is formed between the first portion 231A and the second portion 231B in the first direction x. The two second dam bars 84 are connected to the opposite ends in the second direction y of each of the lead 81 corresponding to the first pad portion 211 of the first die pad 21, the lead 81 corresponding to the second pad portion 221 of the second die pad 22, and the metal portion 232.

As shown in FIG. 25, the first portion 231A of the insulating portion 231 is surrounded by the lead 81 corresponding to the first pad portion 211 of the first die pad 21, the metal portion 232 and the two second dam bars 84. Similarly, the second portion 231B of the insulating portion 231 is surrounded by the lead 81 corresponding to the second pad portion 221 of the second die pad 22, the metal portion 232 and the two second dam bars 84.

FIG. 26 shows the state after the two second dam bars 84 are removed by etching. In this state, the metal portion 232 is supported by the first portion 231A and the second portion 231B of the insulating portion 231 at the opposite ends in the first direction x. In addition, the first portion 231A is supported by the lead 81 corresponding to the first pad portion 211 of the first die pad 21, and the second portion 231B is supported by the lead 81 corresponding to the second pad portion 221 of the second die pad 22. Through the above processes, the support member 23 of the semiconductor device A4 is obtained.

The following describes advantages of the semiconductor device A4.

The semiconductor device A4 includes: a plurality of conductive members 20 including a first die pad 21 and a second die pad 22 spaced apart from each other in the first direction x; a first semiconductor element 11; a second semiconductor element 12; an insulating element 13 that insulates the first semiconductor element 11 and the second semiconductor element 12 from each other; and a sealing resin 50. The semiconductor device A4 also includes a support member 23 on which the insulating element 13 is mounted. The support member 23 includes an insulating portion 231 that contains a resin. The support member 23 is supported by at least one of the first die pad 21, the second die pad 22 and the sealing resin 50. The semiconductor device A4 can therefore improve the dielectric strength between the semiconductor elements (the first semiconductor element 11 and the second semiconductor element 12) and the insulating element 13. In addition, the semiconductor device A4 has a configuration in common with the semiconductor device A1, thereby achieving the same effect as the semiconductor device A1.

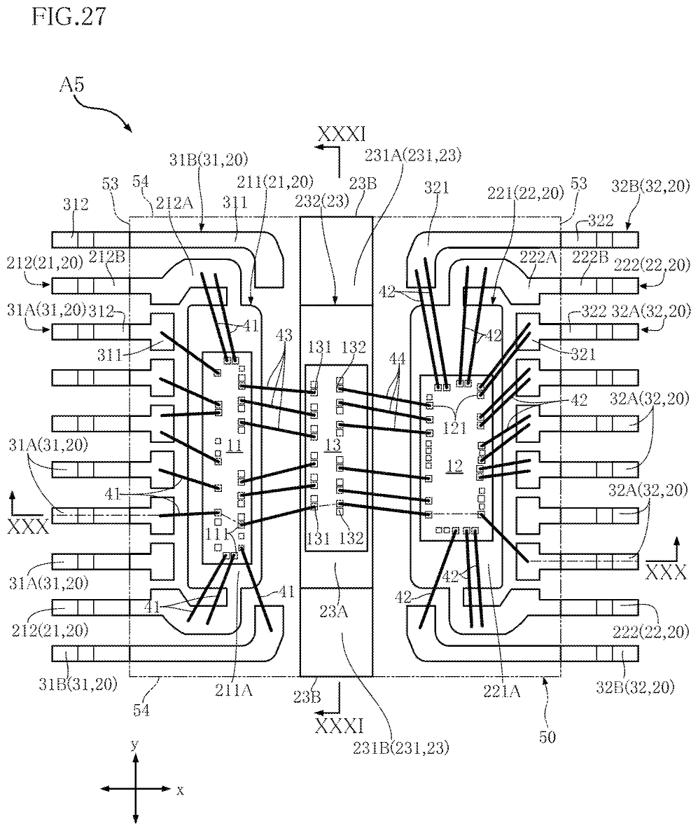

With reference to FIGS. 27 to 31, the following describes a semiconductor device A5 according to a fifth embodiment of the present disclosure. In these figures, the identical or similar elements to those of the semiconductor device Al described above are denoted by the same reference signs, and descriptions of such elements are omitted. For the convenience of description, FIG. 27 shows the sealing resin 50 as transparent and indicates the sealing resin 50 with imaginary lines.

The semiconductor device A5 differs from the semiconductor device A4 described above in the insulating portion 231 of the configuration of the support member 23.

As shown in FIGS. 27 and 31, the insulating portion 231 of the support member 23 includes a first portion 231A and a second portion 231B located with the metal portion 232 in between. The first portion 231A and the second portion 231B are spaced apart from each other in the second direction y. That is, the support member 23 of the semiconductor device A5 is spaced apart from the first die pad 21 and the second die pad 22. Hence, the support member 23 of the semiconductor device A5 is supported by the sealing resin 50.

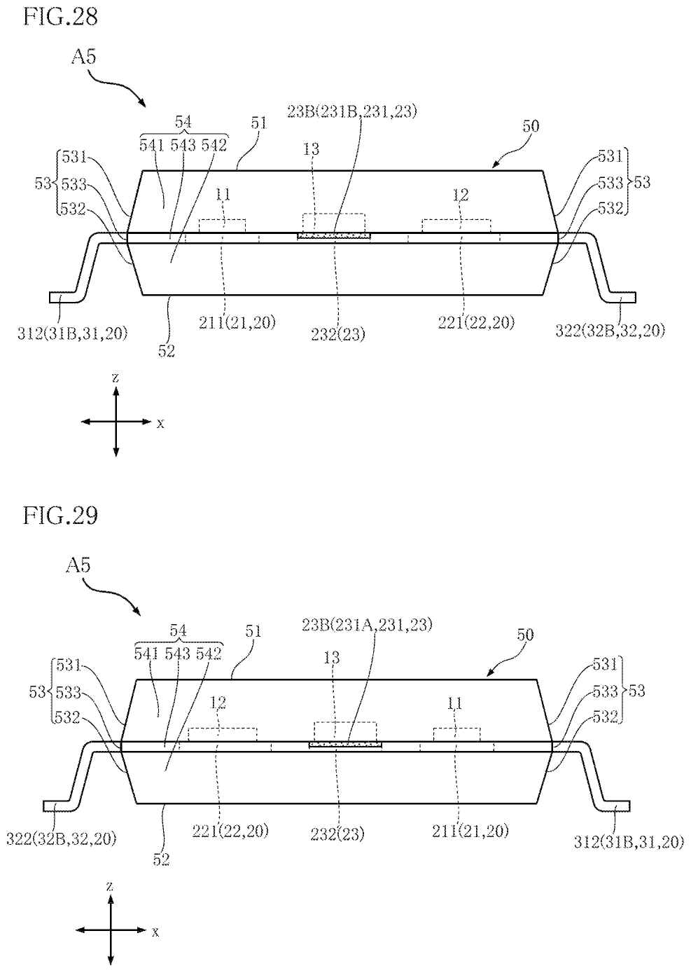

As shown in FIG. 31, each of the first portion 231A and the second portion 231B of the insulating portion 231 has an end surface 23B facing in the second direction y. As shown in FIG. 29, the end surface 23B of the first portion 231A is exposed from the sealing resin 50, more specifically, from the second middle portion 543 of the second side surface 54 located on the first side in the second direction y. Similarly, as shown in FIG. 28, the end surface 23B of the second portion 231B is exposed from the second middle portion 543 of the second side surface 54 located on the second side in the second direction y. That is, the insulating portion 231 of the semiconductor device A5 includes the first portion 231A and the second portion 231B that are exposed from the opposite sides of the sealing resin 50 in the second direction y.

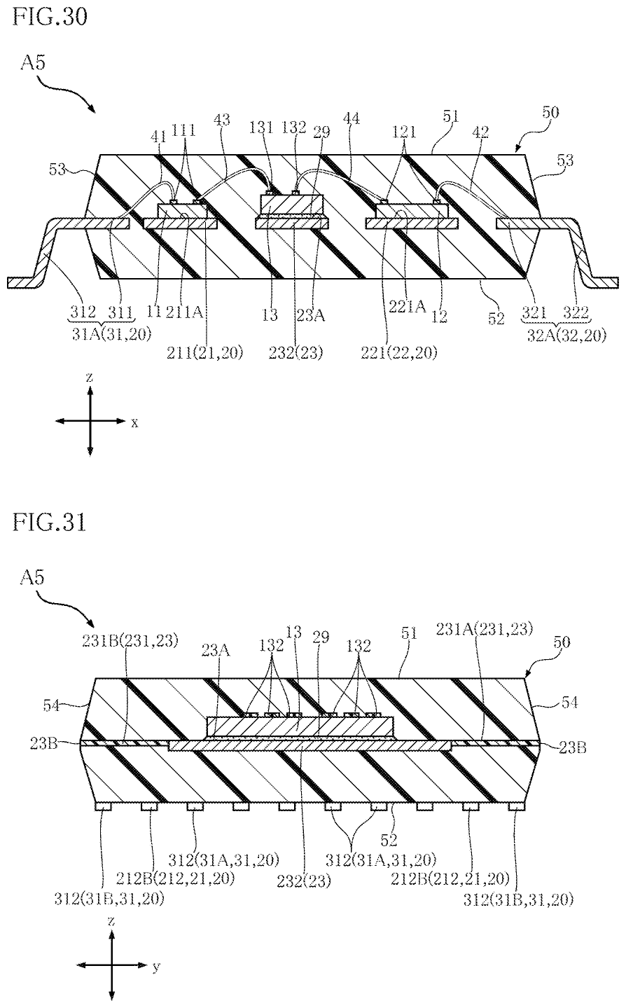

As shown in FIGS. 27 and 30, the third wires 43 extend across the space between the first pad portion 211 of the first die pad 21 and the metal portion 232 of the support member 23. The fourth wires 44 extend across the space 35 between the metal portion 232 and the second pad portion 221 of the second die pad 22.

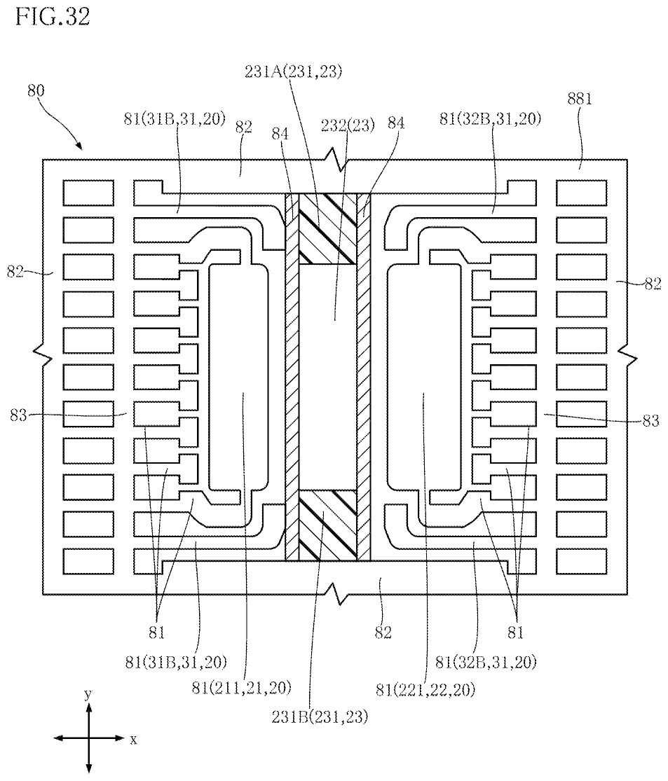

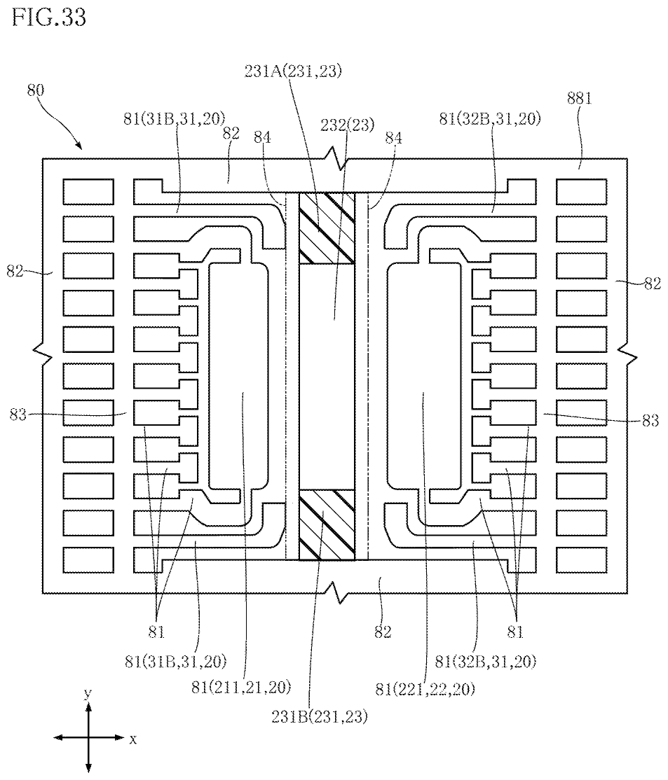

Next, with reference to FIGS. 32 and 33, the following describes one example of a method of forming the support member 23 of the semiconductor device A5.

FIG. 32 shows the lead frame 80 after the insulating portion 231 of the support member 23 is formed. The insulating portion 231 is formed through the processes similar to those shown in FIGS. 12 to 14 for forming the insulating portion 231 of the semiconductor device A1. In FIG. 32, the hatched areas indicate the first portion 231A and the second portion 231B of the insulating portion 231 and the two second dam bars 84. The metal portion 232 of the support member 23 is formed between the first portion 231A and the second portion 231B of the insulating portion 231 in the second direction y. In the first direction x, the metal portion 232 is located between the two second dam bars 84 extending in the second direction y. The second dam bars 84 are connected to the frame 82 at their opposite ends in the second direction y. The metal portion 232 is connected to the second dam bars 84 at its opposite ends in the first direction x. Each of the first portion 231A and the second portion 231B of the insulating portion 231 is surrounded by the two second dam bars 84, the frame 82 and the metal portion 232.

FIG. 33 shows the state after the two second dam bars 84 are removed by etching. In this state, the metal portion 232 is supported by the first portion 231A and the second portion 231B of the insulating portion 231 at the opposite ends in the second direction y. The first portion 231A and the second portion 231B are supported by the frame 82. The metal portion 232, the first portion 231A and the second portion 231B are spaced apart from any of the leads 81. Through the above processes, the support member 23 of the semiconductor device A5 is obtained.

The following describes advantages of the semiconductor device A5.

The semiconductor device A5 includes: a plurality of conductive members 20 including a first die pad 21 and a second die pad 22 spaced apart from each other in the first direction x; a first semiconductor element 11; a second semiconductor element 12; an insulating element 13 that insulates the first semiconductor element 11 and the second semiconductor element 12 from each other; and a sealing resin 50. The semiconductor device A5 also includes a support member 23 on which the insulating element 13 is mounted. The support member 23 includes an insulating portion 231 that contains a resin. The support member 23 is supported by at least one of the first die pad 21, the second die pad 22 and the sealing resin 50. The semiconductor device A5 can therefore improve the dielectric strength between the semiconductor elements (the first semiconductor element 11 and the second semiconductor element 12) and the insulating element 13. In addition, the semiconductor device A5 has a configuration in common with the semiconductor device Al, thereby achieving the same effect as the semiconductor device A1.

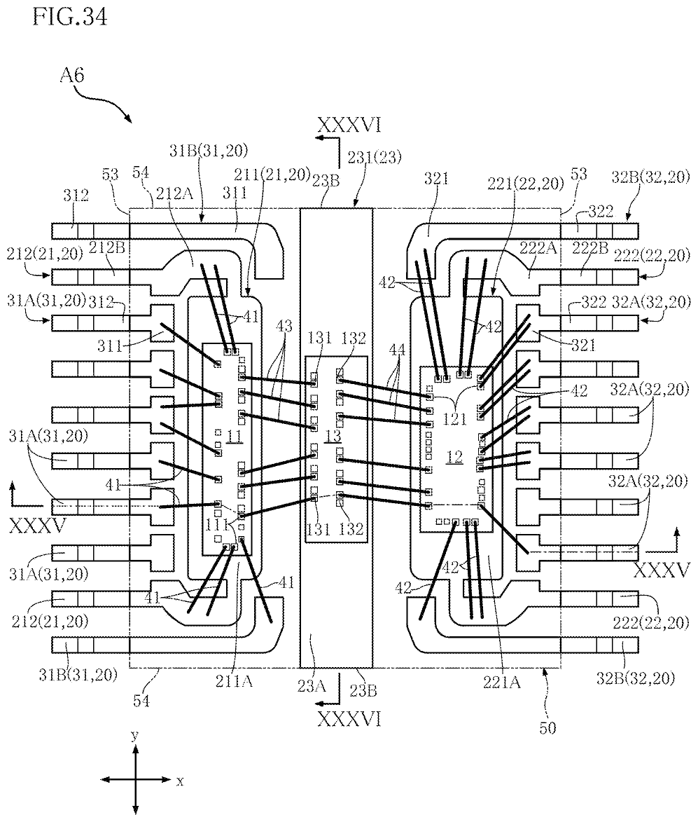

With reference to FIGS. 34 to 36, the following describes a semiconductor device A6 according to a sixth embodiment of the present disclosure. In these figures, the identical or similar elements to those of the semiconductor device A1 described above are denoted by the same reference signs, and descriptions of such elements are omitted. For the convenience of description, FIG. 34 shows the sealing resin 50 as transparent and indicates the sealing resin 50 with imaginary lines.

The semiconductor device A6 differs from the semiconductor device A1 in the configuration of the support member 23.

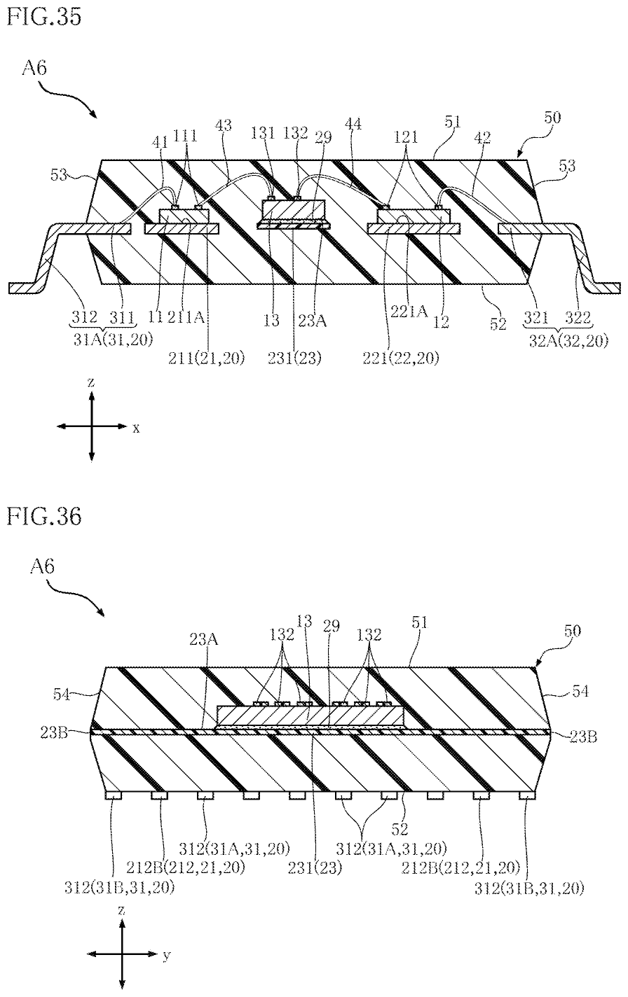

As shown in FIGS. 34 and 35, the support member 23 is located between the first die pad 21 and the second die pad 22 in the first direction x and spaced apart from the first die pad 21 and the second die pad 22. Hence, the support member 23 of the semiconductor device A6 is supported by the sealing resin 50. In the semiconductor device A6, the entire portion of the support member 23 is the insulating portion 231.

As shown in FIG. 36, the insulating portion 231 has a pair of end surfaces 23B facing in the second direction y. One of the end surfaces 23B is exposed from the sealing resin 50, more specifically, from the second middle portion 543 of the second side surface 54 located on the first side in the second direction y (see FIG. 29). The other end surface 23B is exposed from the second middle portion 543 of the second side surface 54 located on the second side in the second direction y (see FIG. 28). That is, the support member 23 of the semiconductor device A6 is exposed from the opposite sides of the sealing resin 50 in the second direction y.

As shown in FIGS. 34 and 35, the third wires 43 extend across the space between the first pad portion 211 of the first die pad 21 and the support member 23. The fourth wires 44 extend across the space between the support member 23 and the second pad portion 221 of the second die pad 22.

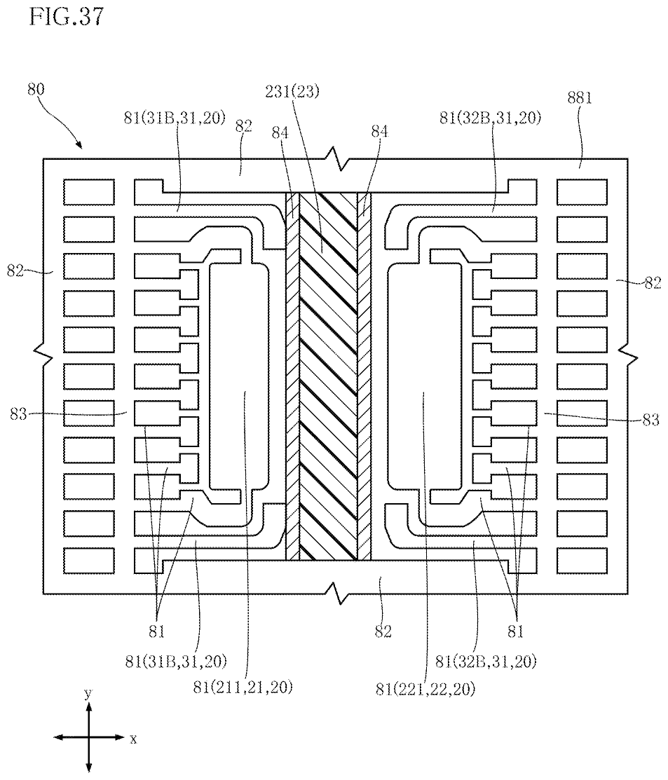

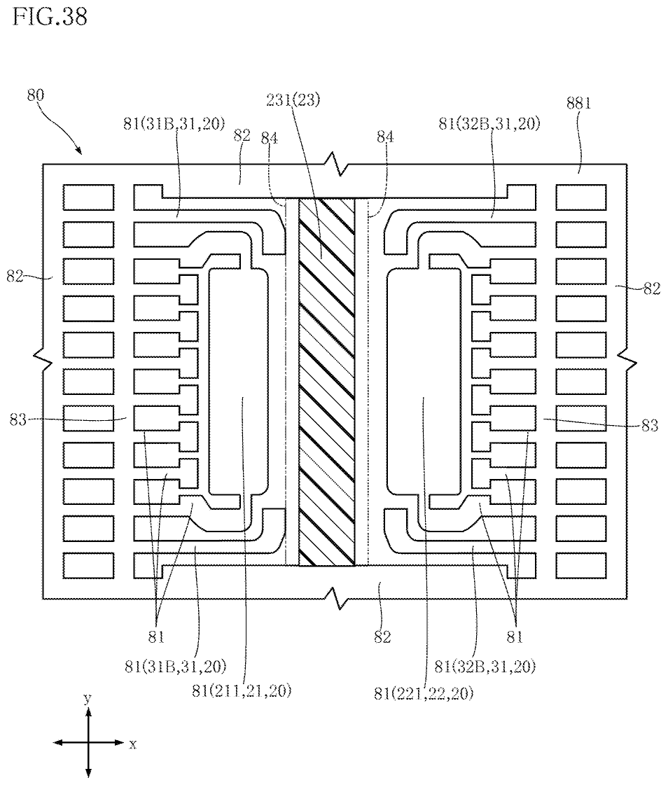

Next, with reference to FIGS. 37 and 38, the following describes one example of a method of forming the support member 23 of the semiconductor device A6.

FIG. 37 shows the lead frame 80 after the insulating portion 231 of the support member 23 is formed. The insulating portion 231 is formed through the processes similar to those shown in FIGS. 12 to 14 for forming the insulating portion 231 of the semiconductor device A1. In FIG. 37, the hatched areas indicate the insulating portion 231 and the two second dam bars 84. The two second dam bars 84 sandwich the insulating portion 231 in the first direction x and extend in the second direction y. The second dam bars 84 are connected to the frame 82 at the opposite ends in the second direction y. The insulating portion 231 is surround by the two second dam bars 84 and the frame 82.

FIG. 38 shows the state after the two second dam bars 84 are removed by etching. In this state, the insulating portion 231 is supported by the frame 82 at the opposite ends in the second direction y. The insulating portion 231 spaced apart from any of the leads 81. Through the above processes, the support member 23 of the semiconductor device A6 is obtained.

Next, the following describes advantages of the semiconductor device A6.

The semiconductor device A6 includes: a plurality of conductive members 20 including a first die pad 21 and a second die pad 22 spaced apart from each other in the first direction x; a first semiconductor element 11; a second semiconductor element 12; an insulating element 13 that insulates the first semiconductor element 11 and the second semiconductor element 12 from each other; and a sealing resin 50. The semiconductor device A6 also includes a support member 23 on which the insulating element 13 is mounted. The support member 23 includes an insulating portion 231 that contains a resin. The support member 23 is supported by at least one of the first die pad 21, the second die pad 22 and the sealing resin 50. The semiconductor device A6 can therefore improve the dielectric strength between the semiconductor elements (the first semiconductor element 11 and the second semiconductor element 12) and the insulating element 13. In addition, the semiconductor device A6 has a configuration in common with the semiconductor device Al, thereby achieving the same effect as the semiconductor device A1.

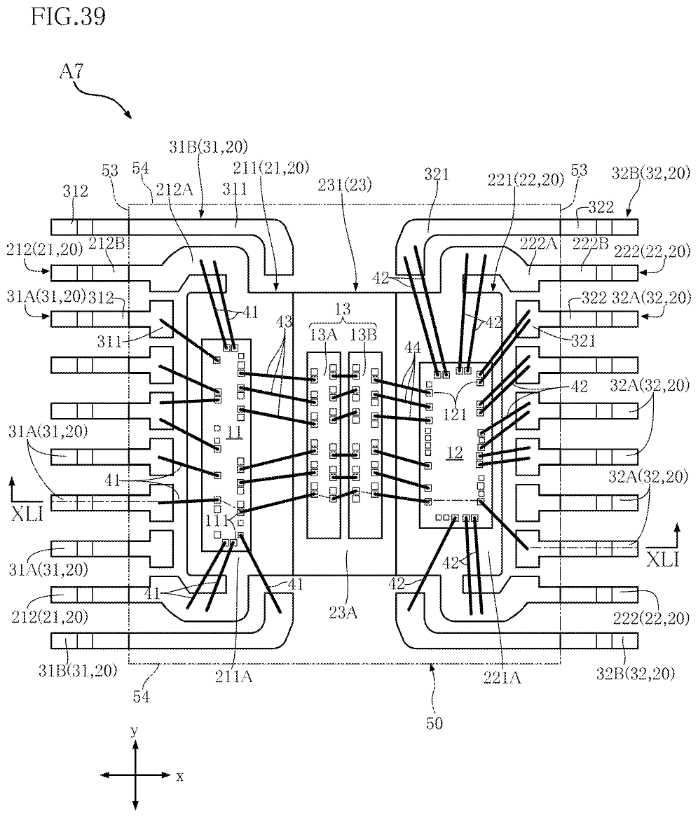

With reference to FIGS. 39 to 42, the following describes a semiconductor device A7 according to a seventh embodiment of the present disclosure. In these figures, the identical or similar elements to those of the semiconductor device Al described above are denoted by the same reference signs, and descriptions of such elements are omitted. For the convenience of description, FIG. 39 shows the sealing resin 50 as transparent and indicates the sealing resin 50 with imaginary lines.

The semiconductor device A7 differs from the semiconductor device A1 described above in the configuration of the insulating element 13. In addition, the semiconductor device A7 includes a plurality of fifth wires 45.

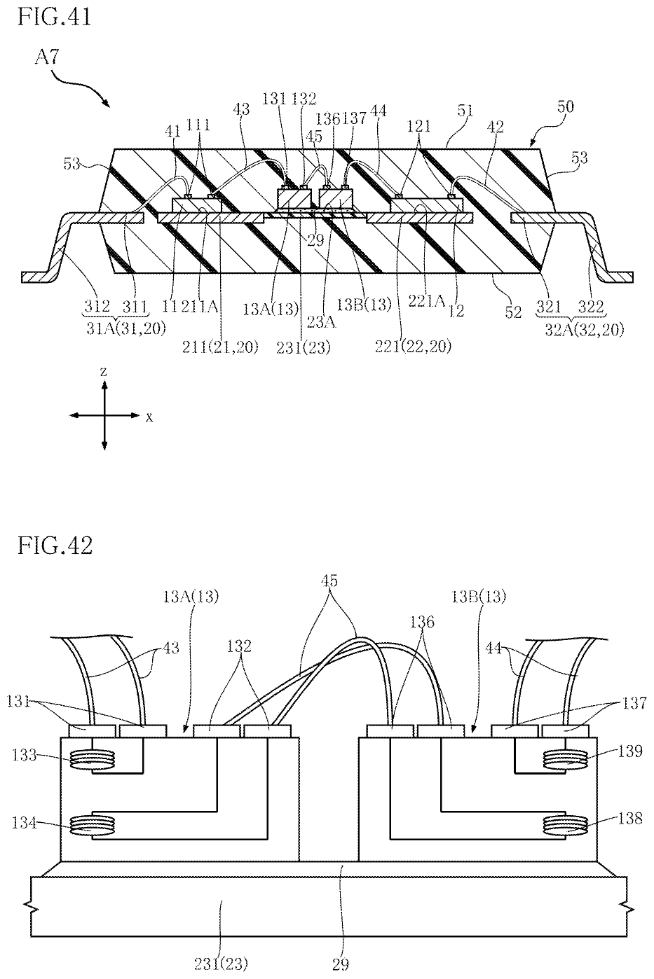

As shown in FIGS. 39 and 41, the insulating element 13 includes a first insulating element 13A and a second insulating element 13B spaced apart from each other. In the semiconductor device A7, the first insulating element 13A and the second insulating element 13B are spaced apart from each other in the first direction x, with the first insulating element 13A located closer to the first semiconductor element 11. The first insulating element 13A and the second insulating element 13B are bonded to the mounting surface 23A of the support member 23 via a bonding layer 29. In the semiconductor device A7, the bonding layer 29 is one continuous layer. In another example, a plurality of separate bonding layers 29 may be provided for the first insulating element 13A and the second insulating element 13B.

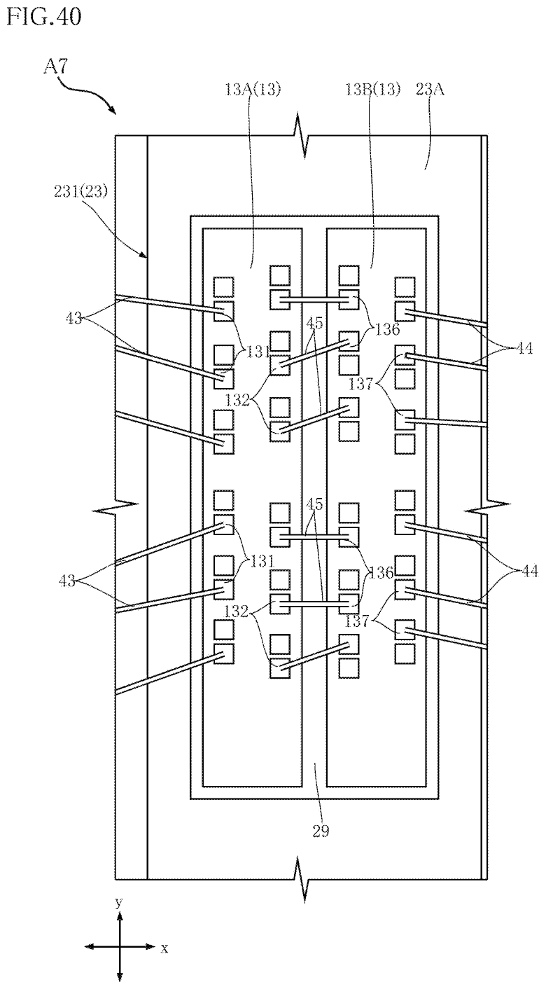

As shown in FIGS. 40 and 41, the first insulating element 13A includes a plurality of first relay electrodes 131 and a plurality of second relay electrodes 132. Each third wire 43 is bonded to a first relay electrode 131 and a first electrode 111 of the first semiconductor element 11. Hence, the first relay electrodes 131 are electrically connected to the first semiconductor element 11.

As shown in FIG. 42, the first insulating element 13A includes a first transmitting/receiving portion 133 and a second transmitting/receiving portion 134. In the semiconductor device A7, the first transmitting/receiving portion 133 and the second transmitting/receiving portion 134 are inductors. The first transmitting/receiving portion 133 and the second transmitting/receiving portion 134 are spaced apart from each other in the thickness direction z. The first insulating element 13A includes a dielectric layer (not shown) made of, for example, silicon dioxide between the first transmitting/receiving portion 133 and the second transmitting/receiving portion 134. The first transmitting/receiving portion 133 is electrically connected to the first relay electrodes 131. Hence, the first transmitting/receiving portion 133 is electrically connected to the first semiconductor element 11. The second transmitting/receiving portion 134 transmits signals to and from the first transmitting/receiving portion 133. The second transmitting/receiving portion 134 is electrically connected to the second relay electrodes 132. In the thickness direction z, the second transmitting/receiving portion 134 is located closer to the support member 23 than the first transmitting/receiving portion 133.

As shown in FIGS. 40 and 41, the second insulating element 13B includes a plurality of third relay electrodes 136 and a plurality of fourth relay electrodes 137. Each fourth wire 44 is bonded to a fourth relay electrode 137 and a second electrode 121 of the second semiconductor element 12. Hence, the fourth relay electrodes 137 are electrically connected to the second semiconductor element 12.

As shown in FIG. 42, the second insulating element 13B includes a third transmitting/receiving portion 138 and a fourth transmitting/receiving portion 139. In the semiconductor device A7, the third transmitting/receiving portion 138 and the fourth transmitting/receiving portion 139 are inductors. The third transmitting/receiving portion 138 and the fourth transmitting/receiving portion 139 are spaced apart from each other in the thickness direction z. The second insulating element 13B includes a dielectric layer (not shown) made of, for example, silicon dioxide between the third transmitting/receiving portion 138 and the fourth transmitting/receiving portion 139. The fourth transmitting/receiving portion 139 is electrically connected to the fourth relay electrodes 137. Hence, the fourth transmitting/receiving portion 139 is electrically connected to the second semiconductor element 12. The third transmitting/receiving portion 138 transmits signals to and from the fourth transmitting/receiving portion 139. The third transmitting/receiving portion 138 is electrically connected to the third relay electrodes 136. In the thickness direction z, the third transmitting/receiving portion 138 is located closer to the support member 23 than the fourth transmitting/receiving portion 139.

As shown in FIGS. 40 and 41, each fifth wire 45 is connected to a third relay electrode 136 of the second insulating element 13B and a second relay electrode 132 of the first insulating element 13A. The fifth wires 45 contains gold. With the fifth wires 45, the second relay electrodes 132 and the third relay electrodes 136 are electrically connected. Hence, the third transmitting/receiving portion 138 of the second insulating element 13B is electrically connected to the second transmitting/receiving portion 134 of the first insulating element 13A. This means that the potential at the third transmitting/receiving portion 138 is equal to the potential at the second transmitting/receiving portion 134. That is, the second transmitting/receiving portion 134 and the third transmitting/receiving portion 138 are held at a potential that is between the potential at the first transmitting/receiving portion 133 of the first insulating element 13A and the potential at the fourth transmitting/receiving portion 139 of the second insulating element 13B.

The support member 23 on which the first insulating element 13A and the second insulating element 13B are mounted is identical in configuration to the support member 23 of the semiconductor device Al. In another example, the support member 23 on which the first insulating element 13A and the second insulating element 13B are mounted may be identical in configuration to the support member 23 of any of the semiconductor devices A1 to A6.

Next, the following describes advantages of the semiconductor device A7.

The semiconductor device A7 includes: a plurality of conductive members 20 including a first die pad 21 and a second die pad 22 spaced apart from each other in the first direction x; a first semiconductor element 11; a second semiconductor element 12; an insulating element 13 that insulates the first semiconductor element 11 and the second semiconductor element 12 from each other; and a sealing resin 50. The semiconductor device A7 also includes a support member 23 on which the insulating element 13 is mounted. The support member 23 includes an insulating portion 231 that contains a resin. The support member 23 is supported by at least one of the first die pad 21, the second die pad 22 and the sealing resin 50. The semiconductor device A7 can therefore improve the dielectric strength between the semiconductor elements (the first semiconductor element 11 and the second semiconductor element 12) and the insulating element 13. In addition, the semiconductor device A7 has a configuration in common with the semiconductor device A1, thereby achieving the same effect as the semiconductor device A1.

The insulating element 13 of the semiconductor device A7 includes a first insulating element 13A and a second insulating element 13B that are spaced apart from each other. The first insulating element 13A includes a first transmitting/receiving portion 133 and a second transmitting/receiving portion 134. The second insulating element 13B includes a third transmitting/receiving portion 138 and a fourth transmitting/receiving portion 139. The third transmitting/receiving portion 138 is electrically connected to the second transmitting/receiving portion 134. In the thickness direction z, the second transmitting/receiving portion 134 and the third transmitting/receiving portion 138 are located closer to the support member 23 than the first transmitting/receiving portion 133 and the fourth transmitting/receiving portion 139. This configuration serves to reduce the potential difference developed in the first insulating element 13A, between the first transmitting/receiving portion 133 and the second transmitting/receiving portion 134. This configuration also serves to reduce the potential difference developed in the second insulating element 13B, between the third transmitting/receiving portion 138 and the fourth transmitting/receiving portion 139. Hence, the potential difference occurring in each of the first insulating element 13A and the second insulating element 13B is reduced. In addition, the potential difference between the upper surface (the mounting surface 23A) of the support member 23 and the lower surface of the insulating element 13 facing the upper surface is also reduced. This is effective for improving the dielectric strength between the support member 23 and the insulating element 13. Unlike the semiconductor device A1, in addition, the semiconductor device A7 makes it possible to omit the relay portion 135 in the insulating element 13.

The present disclosure is not limited to the forgoing embodiments. Various design changes can be made to the specific configuration of each element or portion of the present disclosure.

The present disclosure include embodiments according to the following clauses.

Clause 1. A semiconductor device comprising:

a plurality of conductive members including a first die pad and a second die pad;

a first semiconductor element mounted on the first die pad;

a second semiconductor element mounted on the second die pad;

an insulating element electrically connected to the first semiconductor element and the second semiconductor element and electrically insulating the first semiconductor element and the second semiconductor element from each other;

a sealing resin covering the first semiconductor element, the second semiconductor element, the insulating element and at least a portion of each of the plurality of conductive members; and

a support member on which the insulating element is mounted, at least a portion of the support member being an insulating portion containing a resin,

wherein the first die pad and the second die pad are spaced apart from each other in a first direction orthogonal to a thickness direction of the first semiconductor element, and

the support member is supported by at least one of the first die pad, the second die pad and the sealing resin.

Clause 2. The semiconductor device according to Clause 1, wherein the support member is in contact with at least one of the first die pad and the second die pad.

Clause 3. The semiconductor device according to Clause 2, wherein the support member is located between the first die pad and the second die pad in the first direction, and

the support member is supported by the first die pad and the second die pad.

Clause 4. The semiconductor device according to Clause 2, wherein the first die pad includes a recess that is recessed in the thickness direction, and

the support member is accommodated in the recess.

Clause 5. The semiconductor device according to Clause 2, wherein the second die pad includes a recess that is recessed in the thickness direction, and

the support member is accommodated in the recess.

Clause 6. The semiconductor device according to Clause 1, wherein the support member is located between the first die pad and the second die pad in the first direction and includes a metal portion supported by the insulating portion,

the metal portion is identical in composition to the plurality of conductive members,

the insulating element is mounted on the metal portion, and

the insulating portion includes a first portion and a second portion sandwiching the metal portion in between.

Clause 7. The semiconductor device according to Clause 6, wherein the first portion and the second portion are spaced apart from each other in the first direction,

the first portion is in contact with the first die pad, and

the second portion is in contact with the second die pad.

Clause 8. The semiconductor device according to Clause 6, wherein the first portion and the second portion are spaced apart from each other in a second direction orthogonal to the thickness direction and the first direction, and

the first portion and the second portion are exposed from opposite sides of the sealing resin in the second direction.

Clause 9. The semiconductor device according to Clause 1, wherein the support member is located between the first die pad and the second die pad in the first direction and spaced apart from the first die pad and the second die pad, and

the support member is exposed from opposite sides of the sealing resin in a second direction orthogonal to the thickness direction and the first direction.

Clause 10. The semiconductor device according to any one of Clauses 1 to 9, wherein the plurality of conductive members include a plurality of first terminal exposed from a first side of the sealing resin in the first direction and a plurality of second terminals exposed from a second side of the sealing resin in the first direction,

the first semiconductor element is electrically connected to the plurality of first terminals, and

the second semiconductor element is electrically connected to the plurality of second terminals.

Clause 11. The semiconductor device according to Clause 10, wherein the plurality of first terminals are arranged side by side in a second direction orthogonal to the thickness direction and the first direction, and the plurality of second terminals arranged side by side in the second direction.

Clause 12. The semiconductor device according to Clause 11, wherein the first die pad includes a first pad portion on which the first semiconductor element is mounted and two first suspending-lead portions connected to opposite ends of the first pad portion in the second direction, and

the two first suspending-lead portions are exposed from the first side of the sealing resin in the first direction.

Clause 13. The semiconductor device according to Clause 12, wherein the second die pad includes a second pad portion on which the second semiconductor element is mounted and two second suspending-lead portions connected to opposite ends of the second pad portion in the second direction, and

the two second suspending-lead portions are exposed from the second side of the sealing resin in the first direction.

Clause 14. The semiconductor device according to any one of Clauses 1 to 13, the insulating element is of one of an interactive type or a capacitive type.

Clause 15. The semiconductor device according to Clause 14, wherein the insulating element includes a first transmitting/receiving portion electrically connected to the first semiconductor element, a second transmitting/receiving portion electrically connected to the second semiconductor element, and a relay portion transmitting a signal between the first transmitting/receiving portion and the second transmitting/receiving portion, and

in the thickness direction, the relay portion is located closer to the support member than the first transmitting/receiving portion and the second transmitting/receiving portion.

Clause 16. The semiconductor device according to Clause 14, wherein the insulating element comprises a first insulating element and a second insulating element that are spaced apart from each other,

the first insulating element includes a first transmitting/receiving portion electrically connected to the first semiconductor element, and a second transmitting/receiving portion transmitting a signal to and from the first transmitting/receiving portion, and

the second insulating element includes a third transmitting/receiving portion electrically connected to the second transmitting/receiving portion, and a fourth transmitting/receiving portion electrically connected to the second semiconductor element and transmitting a signal to and from the third transmitting/receiving portion, and

in the thickness direction, the second transmitting/receiving portion and the third transmitting/receiving portion are located closer to the support member than the first transmitting/receiving portion and the fourth transmitting/receiving portion.

Clause 17. The semiconductor device according to any one of Clauses 1 to 16, further comprising a bonding layer between the support member and the insulating element,

wherein the bonding layer is electrically insulating.

### REFERENCE SIGNS

A1, A2, A3, A4, A5, A6, A7: Semiconductor device
11: First semiconductor element 111: First electrode
12: Second semiconductor element 121: Second electrode
13: Insulating element 13A: First insulating element
13B: Second insulating element 131: First relay electrode
132: Second relay electrode
133: First transmitting/receiving portion
134: Second transmitting/receiving portion
135: Relay portion
136: Third relay electrode 137: Fourth relay electrode
138: Third transmitting/receiving portion
139: Fourth transmitting/receiving portion
20: Conductive member 21: First die pad
211: First pad portion 211A: First mounting surface
211B: Recess 212: First suspending-lead portion
212A: Covered portion 212B: Exposed portion
22: Second die pad 221: Second pad portion
221A: Second mounting surface 221B: Recess
222: Second suspending-lead portion 222A: Covered portion
222B: Exposed portion 23: Support member
23A: Mounting surface 23B: End surface
231: Insulating portion 231A: First portion
231B: Second portion 232: Metal portion
29: Bonding layer 31: First terminal
31A: First inner terminal 31B: First outer terminal
311: Covered portion 312: Exposed portion
32: Second terminal 32A: Second inner terminal
32B: Second outer terminal 321: Covered portion
322: Exposed portion 41: First wire
42: Second wire 43: Third wire
44: Fourth wire 45: Fifth wire
50: Sealing resin 51: Top surface
52: Bottom surface 53: First side surface
531: First upper portion 532: First lower portion
533: First middle portion 54: Second side surface
541: Second upper portion 542: Second lower portion
543: Second middle portion 80: Lead frame
80A: Obverse surface 80B: Reverse surface
80C: Recess 81: Lead
82: Frame 83: First dam bar
84: Second dam bar 88: First resist layer
881: First opening 89: Second resist layer
891: Second opening z: Thickness direction
x: First direction y: Second direction

1. A semiconductor device comprising:
a plurality of conductive members including a first die pad and a second die pad;
a first semiconductor element mounted on the first die pad;
a second semiconductor element mounted on the second die pad;
an insulating element electrically connected to the first semiconductor element and the second semiconductor element and electrically insulating the first semiconductor element and the second semiconductor element from each other;
a sealing resin covering the first semiconductor element, the second semiconductor element, the insulating element and at least a portion of each of the plurality of conductive members; and
a support member on which the insulating element is mounted, at least a portion of the support member being an insulating portion containing a resin,
wherein the first die pad and the second die pad are spaced apart from each other in a first direction orthogonal to a thickness direction of the first semiconductor element, and
the support member is supported by at least one of the first die pad, the second die pad and the sealing resin.

2. The semiconductor device according to claim 1, wherein the support member is in contact with at least one of the first die pad and the second die pad.

3. The semiconductor device according to claim 2, wherein the support member is located between the first die pad and the second die pad in the first direction, and
the support member is supported by the first die pad and the second die pad.

4. The semiconductor device according to claim 2, wherein the first die pad includes a recess that is recessed in the thickness direction, and
the support member is accommodated in the recess.

5. The semiconductor device according to claim 2, wherein the second die pad includes a recess that is recessed in the thickness direction, and the support member is accommodated in the recess.

6. The semiconductor device according to claim 1, wherein the support member is located between the first die pad and the second die pad in the first direction and includes a metal portion supported by the insulating portion,
the metal portion is identical in composition to the plurality of conductive members,
the insulating element is mounted on the metal portion, and
the insulating portion includes a first portion and a second portion sandwiching the metal portion in between.

7. The semiconductor device according to claim 6, wherein the first portion and the second portion are spaced apart from each other in the first direction,
the first portion is in contact with the first die pad, and
the second portion is in contact with the second die pad.

8. The semiconductor device according to claim 6, wherein the first portion and the second portion are spaced apart from each other in a second direction orthogonal to the thickness direction and the first direction, and
the first portion and the second portion are exposed from opposite sides of the sealing resin in the second direction.

9. The semiconductor device according to claim 1, wherein the support member is located between the first die pad and the second die pad in the first direction and spaced apart from the first die pad and the second die pad, and
the support member is exposed from opposite sides of the sealing resin in a second direction orthogonal to the thickness direction and the first direction.

10. The semiconductor device according to claim 1, wherein the plurality of conductive members include a plurality of first terminal exposed from a first side of the sealing resin in the first direction and a plurality of second terminals exposed from a second side of the sealing resin in the first direction,
the first semiconductor element is electrically connected to the plurality of first terminals, and
the second semiconductor element is electrically connected to the plurality of second terminals.

11. The semiconductor device according to claim 10, wherein the plurality of first terminals are arranged side by side in a second direction orthogonal to the thickness direction and the first direction, and the plurality of second terminals arranged side by side in the second direction.

12. The semiconductor device according to claim 11, wherein the first die pad includes a first pad portion on which the first semiconductor element is mounted and two first suspending-lead portions connected to opposite ends of the first pad portion in the second direction, and
the two first suspending-lead portions are exposed from the first side of the sealing resin in the first direction.

13. The semiconductor device according to claim 12, wherein the second die pad includes a second pad portion on which the second semiconductor element is mounted and two second suspending-lead portions connected to opposite ends of the second pad portion in the second direction, and
the two second suspending-lead portions are exposed from the second side of the sealing resin in the first direction.

14. The semiconductor device according to claim 1, the insulating element is of one of an interactive type or a capacitive type.

15. The semiconductor device according to claim 14, wherein the insulating element includes a first transmitting/receiving portion electrically connected to the first semiconductor element, a second transmitting/receiving portion electrically connected to the second semiconductor element, and a relay portion transmitting a signal between the first transmitting/receiving portion and the second transmitting/receiving portion, and
in the thickness direction, the relay portion is located closer to the support member than the first transmitting/receiving portion and the second transmitting/receiving portion.

16. The semiconductor device according to claim 14, wherein the insulating element comprises a first insulating element and a second insulating element that are spaced apart from each other,
the first insulating element includes a first transmitting/receiving portion electrically connected to the first semiconductor element, and a second transmitting/receiving portion transmitting a signal to and from the first transmitting/receiving portion, and
the second insulating element includes a third transmitting/receiving portion electrically connected to the second transmitting/receiving portion, and a fourth transmitting/receiving portion electrically connected to the second semiconductor element and transmitting a signal to and from the third transmitting/receiving portion, and
in the thickness direction, the second transmitting/receiving portion and the third transmitting/receiving portion are located closer to the support member than the first transmitting/receiving portion and the fourth transmitting/receiving portion.

17. The semiconductor device according to claim 1, further comprising a bonding layer between the support member and the insulating element,
wherein the bonding layer is electrically insulating.
